(19) United States
(12) Patent Application Publication
(10) Pub. No.: US 2026/0157078 A1
(43) Pub. Date: Jun. 4, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-Si (KR)

(72) Inventors: SEUL-KI KIM, Yongin-si (KR); JEONG HWAN KIM, Yongin-si (KR); ILBAE AHN, Yongin-si (KR); SEOHEE LEE, Yongin-si (KR); JIN-WON LEE, Yongin-si (KR); DOHYUN JUNG, Yongin-si (KR)

(21) Appl. No.: 19/331,271

(22) Filed: Sep. 17, 2025

(30) Foreign Application Priority Data
Dec. 4, 2024 (KR) 10-2024-0178290

(51) Int. Cl. H10K 59/80; H10K 59/12; H10K 59/122; H10K 59/88; H10K 102/10

(52) U.S. Cl. CPC H10K 59/80518; H10K 59/1201; H10K 59/122; H10K 59/80524; H10K 59/88; H10K 2102/102; H10K 2102/103

(57) ABSTRACT

A display device is disclosed that includes a substrate including a display area including a first pixel area and a second pixel area which are adjacent to each other and a pad area spaced apart from the display area, a first reflection electrode disposed in the first pixel area on the substrate, a second reflection electrode disposed in the second pixel area on the substrate, a first transparent electrode disposed in the first pixel area on the first reflection electrode, a first thickness compensation layer disposed in the first pixel area on the first transparent electrode, and including a different material with the first transparent electrode, and a second thickness compensation layer disposed on the first thickness compensation layer, and including a center portion and an edge portion which has an inclination angle with respect to a surface of the first thickness compensation layer.

### CROSS-REFERENCE TO RELATED APPLICATION(S)

This application claims priority under 35 U.S.C. §119 to Korean Patent Application No. 10-2024-0178290, filed on Dec. 4, 2024, which is hereby incorporated by reference for all purposes as if fully set forth herein.

### BACKGROUND

### 1. Field

Embodiments relate to a display device, a method of manufacturing the same, and an electronic device including the same. More particularly, embodiments relate to a display device including a reflection electrode, a method of manufacturing the same, and an electronic device including the same.

### 2. Description of the Related Art

As utilization of display devices becomes more diverse, interest in large display devices such as a large televisions, automobile displays, and smartphones continues. A display device may include a light-emitting element that emits light. The light-emitting element may include an anode and a cathode with a light-emitting layer interposed between the anode and the cathode.

As is being conducted on making larger display devices, technologies for brightness uniformity and brightness enhancement are being developed.

### SUMMARY

Embodiments provide a display device with improved display quality.

Embodiments provide a method of manufacturing the display device.

Embodiments provide an electronic device including the display device.

A display device according to an embodiment includes a substrate, a first reflection electrode, a second reflection electrode, a first transparent electrode, a first thickness compensation layer, and a second thickness compensation layer. The substrate includes a display area including a first pixel area and a second pixel area which are adjacent to each other and a pad area spaced apart from the display area. The first reflection electrode is disposed in the first pixel area on the substrate. The second reflection electrode is disposed in the second pixel area on the substrate. The first transparent electrode is disposed in the first pixel area on the first reflection electrode. The first thickness compensation layer is disposed in the first pixel area on the first transparent electrode, and including a different material with the first transparent electrode. The second thickness compensation layer is disposed on the first thickness compensation layer. The second thickness compensation layer includes a center portion and an edge portion which has a first inclination angle with respect to a surface of the first thickness compensation layer.

In an embodiment, the first thickness compensation layer may include an indium zinc oxide (IZO), and the second thickness compensation layer may include an indium tin oxide (ITO).

In an embodiment, the display device may further include a pixel defining layer and a common electrode. The pixel defining layer may be disposed on the substrate. The pixel defining layer may cover a portion of each of the first reflection electrode, the second reflection electrode, the first transparent electrode, and the first thickness compensation layer. The common electrode may be disposed in the first pixel area and the second pixel area on the pixel defining layer. A surface of the common electrode may have a first height based on the substrate in the first pixel area. The surface of the common electrode may have a second height different from the first height based on the substrate in the second pixel area.

In an embodiment, the second thickness compensation layer may extend from the center portion along a side surface of the pixel defining layer.

In an embodiment, the display device may further include a second transparent electrode. The second transparent electrode may be disposed in the second pixel area on the second reflection electrode. A first resonance distance defined as a shortest distance between the second thickness compensation layer and the common electrode may be greater than a second resonance distance defined as a shortest distance between the second transparent electrode and the common electrode.

In an embodiment, the display device may further include a dummy pattern. The dummy pattern may be disposed in the second pixel area on the second transparent electrode. The dummy pattern may contact an edge portion of the second transparent electrode. The first thickness compensation layer and the dummy pattern may include a same material.

In an embodiment, the display area may include a third pixel area adjacent to the second pixel area. The display device may further include a third reflection electrode, a third transparent electrode, and a third thickness compensation layer. The third reflection electrode may be disposed on the third pixel area on the substrate. The third transparent electrode may be disposed in the third pixel area on the third reflection electrode. The third thickness compensation layer may be disposed in the third pixel area on the third transparent electrode. A first resonance distance defined as a shortest distance between the second thickness compensation layer and the common electrode may be greater than a third resonance distance defined as a shortest distance between the third thickness compensation layer and the common electrode.

In an embodiment, the second thickness compensation layer and the third thickness compensation layer may include a same material.

In an embodiment, the third thickness compensation layer may extend along a side surface of the pixel defining layer. An edge portion of the third thickness compensation layer may have a second inclination angle with respect to a surface of the third transparent electrode

In an embodiment, the display device may further include an electrode structure, an insulating structure, and a capping layer. The electrode structure may be disposed in the pad area on the substrate. The insulating structure may be disposed in the pad area on the substrate. The insulating structure may cover at least a portion of the electrode structure, and defining an opening exposing at least a portion of the electrode structure. The capping layer may be disposed on the electrode structure. The capping layer may fill the opening. The capping layer and the second thickness compensation layer may include a same material.

A method of manufacturing a display device according to an embodiment includes forming a first pixel electrode in a first pixel area on a substrate including the first pixel area, a second pixel area, and a third pixel area adjacent to each other, forming a first thickness compensation layer in the first pixel area on the first pixel electrode, forming a first conductive layer in the first pixel area, the second pixel area, and the third pixel area on the first thickness compensation layer, and forming a second thickness compensation layer directly contacting the first thickness compensation layer in the first pixel area, and including an edge portion having a first inclination angle with respect to a surface of the first conductive layer.

In an embodiment, the forming of the first pixel electrode may include forming a second conductive layer in the first pixel area, the second pixel area, and the third pixel area on the substrate, forming a third conductive layer in the first pixel area, the second pixel area, and the third pixel area on the second conductive layer, forming a first photoresist in the pixel area on the third conductive layer, forming a second photoresist having a thickness equal to a thickness of the first photoresist in the second area on the third conductive layer, forming a third photoresist having a thickness less than a thickness of the first photoresist in the third pixel area on the third conductive layer, and removing a portion of the second conductive layer spaced apart from the first photoresist, the second photoresist, and the third photo resist in a plan view.

In an embodiment, in the removing of the portion of the second conductive layer, the portion of the second conductive layer may be removed to form the second pixel electrode in the second pixel area and to form the third pixel electrode in the third pixel area.

In an embodiment, the forming of the first thickness compensation layer may include removing a portion of the third conductive layer space apart from the first photoresist, the second photoresist, and the third photoresist in a plan view, removing the portion of the third conductive layer to form a first preliminary thickness compensation layer in the first pixel area on the first pixel electrode, removing the portion of the third conductive layer to form a second preliminary thickness compensation layer in the second pixel area on the second pixel electrode, removing the portion of the third conductive layer to form a third preliminary thickness compensation layer in the third pixel area on the third pixel electrode, ashing each of the first photoresist, the second photoresist, and the third photoresist to expose a surface of the third preliminary thickness compensation layer, and etching each of the first preliminary thickness compensation layer, the second preliminary thickness compensation layer, and the third preliminary thickness compensation layer using an etchant.

In an embodiment, performing a process of ashing may include ahsing the first photoresist to remove a portion of the first photoresist, ahsing the second photoresist to remove a portion of the second photoresist, and ahsing the third photoresist to remove entirety of the third photoresist.

In an embodiment, etching of the first preliminary thickness compensation layer, the second preliminary thickness compensation layer, and the third preliminary thickness compensation layer may include removing a portion of the first preliminary thickness compensation layer using an etchant an etching selectivity for the third conductive layer greater than an etching selectivity for the second conductive layer, removing a portion of the second preliminary thickness compensation layer using the etchant, and removing entirety of the third preliminary thickness compensation layer using the etchant.

In an embodiment, forming of the first conductive layer may include forming a pixel defining layer partially overlapping each of the first pixel electrode, the second pixel electrode, and the third pixel electrode in a plan view and depositing the first conductive layer on the first thickness compensation layer, the second preliminary thickness compensation layer, the third pixel electrode, and the pixel defining layer. In the forming of the second thickness compensation layer, in the first pixel area, the first conductive layer may beetched so that a portion of the first conductive layer extending along a side surface of the pixel defining layer.

In an embodiment, the method may further include forming a third thickness compensation layer directly contacting the third pixel electrode in the third pixel area, and including an edge portion having a second inclination angle with respect to the third thickness compensation layer by removeing a portion of the first conductive layer. The forming of the third thickness compensation layer may be performed simultaneously with the forming of the second thickness compensation layer.

In an embodiment, the method may further include forming a capping layer including a same material as the second thickness compensation layer on an insulating layer in a pad area on the substrate. The forming of the capping layer may be performed simultaneously with the forming of the second thickness compensation layer.

An electronic device according to an embodiment includes one or more processors and a display device. The processor is configured to output an input data signal and an input control signal. The display device is configured to process the input data signal and the input control signal, and configured to output an image data through a display screen. The display device according to an embodiment includes a substrate, a first reflection electrode, a second reflection electrode, a first transparent electrode, a first thickness compensation layer, and a second thickness compensation layer. The substrate includes a display area including a first pixel area and a second pixel area which are adjacent to each other and a pad area spaced apart from the display area. The first reflection electrode is disposed in the first pixel area on the substrate. The second reflection electrode is disposed in the second pixel area on the substrate. The first transparent electrode is disposed in the first pixel area on the first reflection electrode. The first thickness compensation layer is disposed in the first pixel area on the first transparent electrode, and including a different material with the first transparent electrode. The second thickness compensation layer is disposed on the first thickness compensation layer. The second thickness compensation layer includes a center portion and an edge portion which has an inclination angle with respect to a surface of the first thickness compensation layer.

In a display device according to embodiments of the present disclosure, a first pixel area may include a first reflection electrode, a transparent electrode sequentially disposed on the first reflection electrode, a first thickness compensation layer, and a second thickness compensation layer. In addition, a third pixel area may include a third reflection electrode, a transparent electrode sequentially disposed on the third reflection electrode, and a third thickness compensation layer. Accordingly, a common electrode disposed on the first pixel electrode, the second pixel electrode, and the third pixel electrode have different heights (e.g., heights) in each of the first pixel area, the second pixel area, and the third pixel area, and may secure a target resonance distance depending on a color of light emitted from a light-emitting layer. Accordingly, a resonance phenomenon may be generated between light traveling from the light-emitting layer toward the common electrode and light emitted from the light-emitting layer and reflected by reflection electrodes, so that light-emitting efficiency and display quality of the display device may be improved.

In a method of manufacturing the display device according to embodiments of the present disclosure, using an etchant, a portion of a conductive layer including indium zinc oxide (IZO) disposed in the third pixel area may be removed, a portion of a conductive layer including indium tin oxide (ITO) disposed in the second pixel area and the third pixel area may be removed, and a preliminary thickness compensation layer formed from the conductive layer including indium tin oxide disposed in the second pixel area may be removed. Accordingly, the first thickness compensation layer and the second thickness compensation layer may be formed in the first pixel area, and the third thickness compensation layer may be formed in the third pixel area. Accordingly, the target resonance distance may be secured without directly etching upper transparent electrodes formed on the reflection electrodes. Accordingly, the display device with improved durability may be easily manufactured.

In an electronic device according to embodiments of the present disclosure, the display device including a display module and a processor, a memory and a power module for operating the display module may be disposed in the electronic device. Accordingly, the electronic device which drives the display device with improved light-emitting efficiency and display quality, and which is used for various purposes may be stably operated, and may be provided to a user.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a circuit diagram illustrating a first pixel included in the display device of FIG. 1.

FIG. 3 is a cross-sectional view illustrating an example of a cross-section taken along a line I-I′ of FIG. 1.

FIG. 4 is an enlarged cross-sectional view illustrating an area A of FIG. 3.

FIG. 5 is a cross-sectional view illustrating an example of a cross-section taken along a line II-II′ of FIG. 1.

FIGS. 6, 7, 8, 9, 10, 11, 12, 13, 14, 15, 16, 17, and 18 are cross-sectional views for explaining a method of manufacturing the display device of FIG. 3.

FIG. 19 is a cross-sectional view illustrating another example of a cross-section taken along a line I-I′ of FIG. 1.

FIG. 20 is an enlarged cross-sectional view illustrating an area B of FIG. 19.

FIGS. 21, 22, 23, and 24 are cross-sectional views for explaining a method of manufacturing the display device of FIG. 20.

FIG. 25 is a cross-sectional view illustrating another example of a cross-section taken along a line II-II′ of FIG. 1.

FIGS. 26, 27, 28, and 29 are cross-sectional views for explaining a method of manufacturing the display device of FIG. 25.

FIG. 30 is a block diagram of an electronic device according to an embodiment of the present disclosure.

FIG. 31 is a schematic diagram of the electronic device according to various embodiments of the present disclosure.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

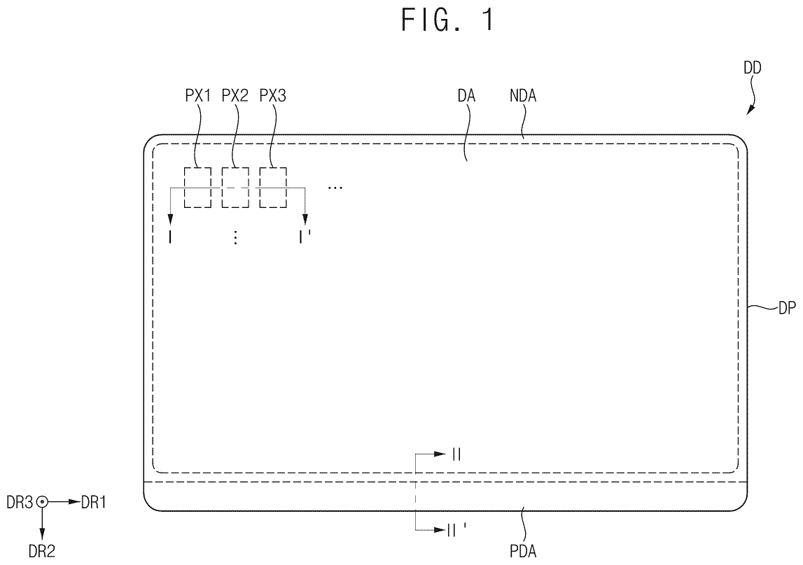

FIG. 1 is a plan view illustrating a display device according to an embodiment of the present disclosure.

Referring to FIG. 1, a display device DD according to an embodiment of the present disclosure may include a display area DA, a non-display area NDA, and a pad area PDA. The display device DD may include a display panel DP. Since the display device DD includes a display area DA, a non-display area NDA, and a pad area PDA, the display panel DP may also include the display area DA, the non-display area NDA, and the pad area PDA.

In the disclosure, a plane may be defined as a first direction DR1 and a second direction DR2 intersecting the first direction DR1. For example, the second direction DR2 may be perpendicular to the first direction DR1. In addition, the third direction DR3 may be perpendicular to the plane.

The display area DA may be defined as an area that generates light or displays an image by controlling the transmittance of light. A plurality of pixels that emit light may be disposed in the display area DA. The plurality of pixels may be disposed within the display area DA. For example, the plurality of pixels may be disposed in the first direction DR1 and the second direction DR2 within the display area DA to form a matrix. The display panel DP may include the plurality of pixels. For example, the plurality of pixels may be disposed in the display area DA of the display panel DP.

In an embodiment, the plurality of pixels may include a first pixel PX1, a second pixel PX2, and a third pixel PX3 that emit light of different colors. In an embodiment, the first pixel PX1 may emit light of a first color. In an embodiment, the second pixel PX2 may emit light of a second color. In an embodiment, the third pixel PX3 may emit light of a third color. In an embodiment, the first light may be red, the second light may be green, and the third light may be blue. However, the color of light emitted by each of the first pixel PX1, the second pixel PX2, and the third pixel PX3 according to the embodiments of the present disclosure may not be limited thereto, and the first pixel PX1, the second pixel PX2, and the third pixel PX3 may be combined to emit light having various colors such as magenta, cyan, and yellow.

In an embodiment, the first pixel PX1, the second pixel PX2, and the third pixel PX3 may be spaced apart from each other in a first direction DR1 in a plan view. In an embodiment, the first pixel PX1, the second pixel PX2, and the third pixel PX3 may be repeatedly disposed along the first direction DR1 and the second direction DR2 in a plan view. However, the spacing direction between the first pixel PX1, the second pixel PX2, and the third pixel PX3 according to the embodiments of the present disclosure and an arrangement direction of the first pixel PX1, the second pixel PX2, and the third pixel PX3 may not be necessarily limited thereto.

The non-display area NDA may be defined as an area where an image generated by the light is not displayed. However, the non-display area NDA according to the embodiments of the present disclosure is not necessarily limited thereto, and a configuration that emits light, (e.g., the first pixel PX1, the second pixel PX2, and the third pixel PX3), may also be disposed in the non-display area NDA.

The non-display area NDA may surround at least a portion of the display area DA. For example, the non-display area NDA may entirely surround the display area DA in a plan view. A driver for driving each of the plurality of pixels may be disposed in the non-display area NDA. The above driver may provide a signal or voltage to each of the plurality of pixels. For example, the driver may include a data driver, a scan driver, a light-emitting driver, a voltage generator, and the like.

The pad area PDA may be spaced apart from the display area DA in a plan view. For example, the pad area PDA may be spaced apart from a side of the display area DA in the second direction DR2. The pad area PDA may be adjacent to the non-display area NDA. A power voltage generator that provides a power voltage to each of the plurality of pixels, a driving controller that controls the operation of the driver, and the like. may be disposed in the pad area PDA. However, disposition of the driver and the driving controller according to the embodiments of the present disclosure may not be necessarily limited thereto. For example, the data driver and the driving controller may be formed integrally, and the data driver and the driving controller formed integrally may be disposed in one area of the non-display area NDA or the pad area PDA.

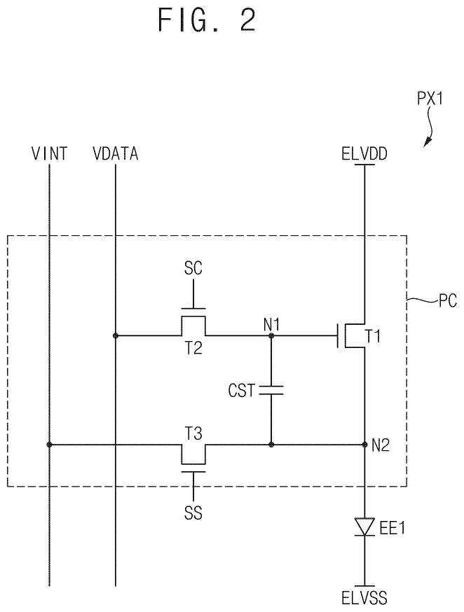

FIG. 2 is a circuit diagram illustrating a first pixel included in the display device of FIG. 1.

Referring to FIG. 2, the first pixel PX1 may include a pixel circuit PC and a first light-emitting element EE1 electrically connected to the pixel circuit PC. The pixel circuit PC may include a first transistor T1, a second transistor T2, a third transistor T3, and a storage capacitor CST.

The first transistor T1 may include a first electrode, a gate electrode, and a second electrode. The gate electrode of the first transistor T1 may be connected to a first node N1. A first power voltage ELVDD may be applied to the first electrode of the first transistor T1. The second electrode of the first transistor T1 may be connected to a second node N2. The first transistor T1 may generate a driving current based on a voltage stored in the storage capacitor CST. The first transistor T1 may be referred to as a driving transistor for generating the driving current. The first transistor T1 may provide the driving current to the first light-emitting element EE1.

The second transistor T2 may include a first electrode, a gate electrode, and a second electrode. A first scan signal SC may be applied to the gate electrode of the second transistor T2. A data voltage VDATA may be applied to the first electrode of the second transistor T2. The second electrode of the second transistor T2 may be connected to the first node N1. The second transistor T2 may be turned on by the first scan signal SC to electrically connect a data voltage line that provides a data voltage VDATA to the first node N1. The second transistor T2 may be referred to as a write transistor or a scan transistor for transmitting the data voltage VDATA.

The third transistor T3 may include a first electrode, a gate electrode, and a second electrode. A second scan signal SS may be applied to the gate electrode of the third transistor T3. The initialization voltage VINT may be applied to the first electrode of the third transistor T3. The second electrode of the third transistor T3 may be connected to the second node N2. The third transistor T3 may be turned on by the second scan signal SS to electrically connect an initialization voltage line that provides an initialization voltage VINT to the second node N2. The third transistor T3 may be referred to as an initialization transistor.

The storage capacitor CST may include a first electrode and a second electrode. The first electrode of the storage capacitor CST may be electrically connected to the first node N1. The second electrode of the storage capacitor CST may be electrically connected to the second node N2. The storage capacitor CST may store a differential voltage between the gate voltage and the source voltage of the first transistor T1.

The first light-emitting element EE1 may include a first terminal (e.g., an anode terminal) and a second terminal (e.g., a cathode terminal). The first terminal of the first light-emitting element EE1 may be connected to a second node N2, and the second terminal may be supplied with a second power voltage ELVSS. The first light-emitting element EE1 may generate light having a brightness corresponding to the driving current. In an embodiment, the first light-emitting element EE1 may emit light of the first color.

In an embodiment, the second power voltage ELVSS may have a different voltage level from the first power voltage ELVDD. For example, a voltage level of the second power voltage ELVSS may be less than a voltage level of the first power voltage ELVDD. Specifically, the voltage level may mean the intensity of the voltage. However, the relationship between the voltage levels of the second power supply voltage ELVSS and the first power supply voltage ELVDD according to embodiments of the present disclosure may not be necessarily limited thereto.

In an embodiment, each of the first, second, and third transistors T1, T2, T3 may be an n-type transistor. However, a type of each of the first, second, and third transistors T1, T2, T3 according to embodiments of the present disclosure may not be necessarily limited thereto, and at least one of the first, second, and third transistors T1, T2, T3 may be a p-type transistor.

FIG. 2 illustrates that the first pixel PX1 includes three transistors and one capacitor, however the number of transistors and capacitors included in a pixel according to embodiments of the present disclosure may not be limited thereto. For example, the first pixel PX1 may include more or less than three transistors, or the first pixel PX1 may include more than one capacitor.

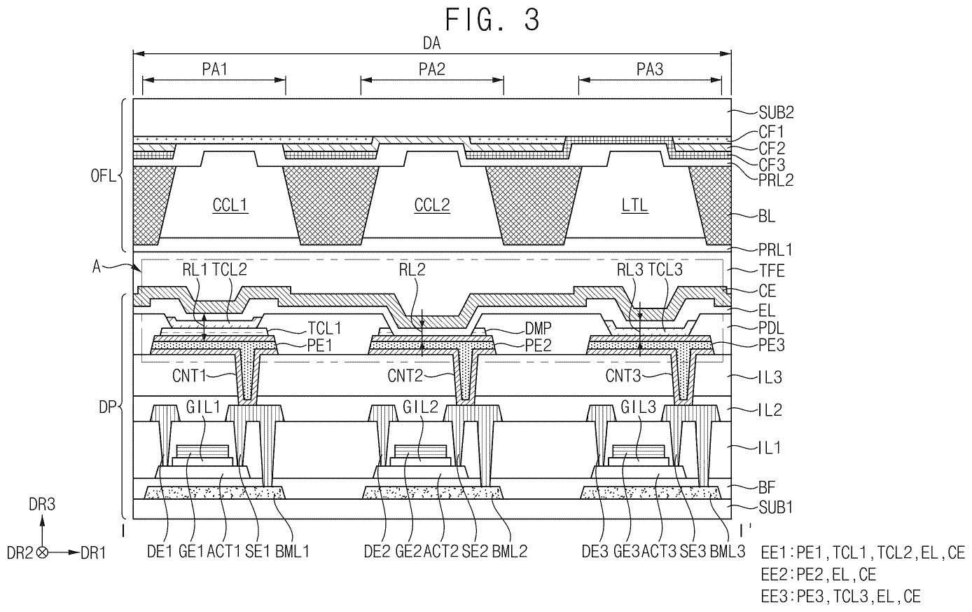

In FIG. 2, the circuit diagram of the first pixel PX1 is illustrated, however circuit diagrams of the second pixel PX2 and the third pixel PX3 may have substantially a same structure as the circuit diagram of the first pixel PX1. For example, the second pixel PX2 may include a second light-emitting element that emits light of the second color (e.g., the second light-emitting element EE2 of FIG. 3) and a pixel circuit PC electrically connected to the second light-emitting element. For example, the third pixel PX3 may include a third light-emitting element that emits light of the third color (e.g., the third light-emitting element EE3 of FIG. 3) and a pixel circuit PC electrically connected to the third light-emitting element.

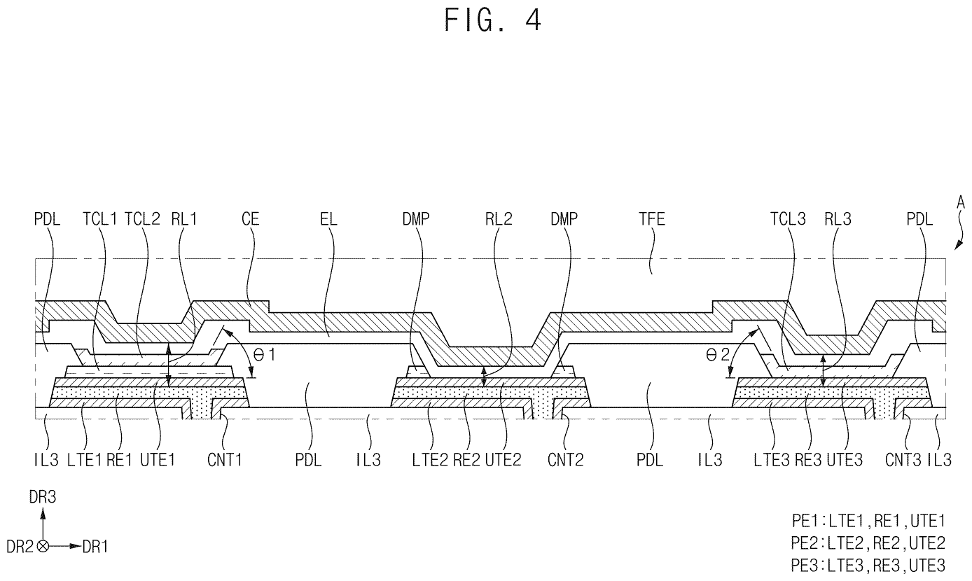

FIG. 3 is a cross-sectional view illustrating an example of a cross-section taken along a line I-I′ of FIG. 1. FIG. 4 is an enlarged cross-sectional view illustrating an area A of FIG. 3.

Referring to FIGS. 3 and 4, the display device DD may include the display panel DP, a thin film encapsulation layer TFE, an optical functional layer OFL, and a second substrate SUB2. The display panel DP may include a first substrate SUB1, a first lower metal layer BML1, a second lower metal layer BML2, a third lower metal layer BML3, a buffer layer BF, a first active layer ACT1, a second active layer ACT2, a third active layer ACT3, a first gate insulating layer GIL1, a second gate insulating layer GIL2, a third gate insulating layer GIL3, a first gate electrode GE1, a second gate electrode GE2, a third gate electrode GE3, a first insulating layer IL1, a first source electrode SE1, a first drain electrode DE1, a second source electrode SE2, a second drain electrode DE2, a third source electrode SE3, a third drain electrode DE3, a second insulating layer IL2, a third insulating layer IL3, a first pixel electrode PE1, a first thickness compensation layer TCL1, a second thickness compensation layer TCL2, a second pixel electrode PE2, a dummy pattern DMP, a third pixel electrode PE3, a third thickness compensation layer TCL3, a pixel defining layer PDL, an light-emitting layer EL, and a common electrode CE. The optical functional layer OFL may include a first protective layer PRL1, a first color conversion layer CCL1, a second color conversion layer CCL2, a light-transmitting layer LTL, a light-blocking member BL, a first color filter CF1, a second color filter CF2, and a third color filter CF3.

The first pixel electrode PE1 may include a first lower transparent electrode LTE1, a first reflection electrode RE1, and a first upper transparent electrode UTE1. The second pixel electrode PE2 may include a second lower transparent electrode LTE2, a second reflection electrode RE2, and a second upper transparent electrode UTE2. The third pixel electrode PE3 may include a third lower transparent electrode LTE3, a third reflection electrode RE3, and a third upper transparent electrode UTE3.

In the disclosure, the first substrate SUB1 may be referred to as a substrate. In addition, the first upper transparent electrode UTE1 may be referred to as a first transparent electrode. In addition, the second upper transparent electrode UTE2 may be referred to as a second transparent electrode. In addition, the third transparent electrode UTE3 may be referred to as a third transparent electrode.

Referring further to FIGS. 1 and 2, the first active layer ACT1, the first gate electrode GE1, the first source electrode SE1, and the first drain electrode DE1 may together define a transistor. For example, the transistor may be one among a plurality of transistors included in the first pixel PX1. Specifically, the transistor may be one among the first, second, and third transistors T1, T2, T3 included in the first pixel PX1. In addition, the first pixel electrode PE1, the first thickness compensation layer TCL1, the second thickness compensation layer TCL2, the light-emitting layer EL, and the common electrode CE may define the first light-emitting element EE1.

The second active layer ACT2, the second gate electrode GE2, the second source electrode SE2, and the second drain electrode DE2 may together define a transistor. For example, the transistor may be one among the plurality of transistors included in the second pixel PX2. In addition, the second pixel electrode PE2, the light-emitting layer EL, and the common electrode CE may define the second light-emitting element EE2.

The third active layer ACT3, the third gate electrode GE3, the third source electrode SE3, and the third drain electrode DE3 may together define a transistor. For example, the transistor may be one of a plurality among transistors included in the third pixel PX3. In addition, the third pixel electrode PE3, the third thickness compensation layer TCL3, the light-emitting layer EL, and the common electrode CE may define a third light-emitting element EE3.

The display area DA may include a first pixel area PA1, a second pixel area PA2, and a third pixel area PA3. For example, the first pixel area PA1 may be an area where the first pixel PX1 is disposed. For example, the second pixel area PA2 may be an area where the second pixel PX2 is disposed. For example, the third pixel area PA3 may be an area where the third pixel PX3 is disposed. In an embodiment, the first pixel area PA1, the second pixel area PA2, and the third pixel area PA3 may be adjacent to each other. In an embodiment, the first pixel area PA1, the second pixel area PA2, and the third pixel area PA3 may be spaced apart from each other in a plan view.

The first substrate SUB1 may serve as a base of the display panel DP. The first substrate SUB1 may include a transparent material or an opaque material. In an embodiment, the first substrate SUB1 may include a transparent resin substrate including polyimide (PI), and the like. For example, when the first substrate SUB1 includes a transparent resin substrate, the first substrate SUB1 may include a first organic layer, a first barrier layer, and a second organic layer that are sequentially stacked in a third direction DR3.

In an embodiment, the first substrate SUB1 may include a quartz substrate, a synthetic quartz substrate, a calcium fluoride substrate, a fluorine-doped quartz substrate, a soda-lime glass substrate, a non-alkali glass substrate, and the like. These may be used alone or in combination.

The first lower metal layer BML1, the second lower metal layer BML2, and the third lower metal layer BML3 may be disposed on the first substrate SUB1. In an embodiment, the first lower metal layer BML1 may be disposed in the first pixel area PA1. In an embodiment, the second lower metal layer BML2 may be disposed in the second pixel area PA2. In an embodiment, the third lower metal layer BML3 may be disposed in the third pixel area PA3.

The first lower metal layer BML1 may prevent impurities from diffusing into the first active layer ACT1 or prevent static electricity from being generated in the first active layer ACT1. The second lower metal layer BML2 may prevent impurities from diffusing into the second active layer ACT2 or prevent static electricity from being generated in the second active layer ACT2. The third lower metal layer BML3 may prevent impurities from diffusing into the third active layer ACT3 or prevent static electricity from being generated in the third active layer ACT3.

In an embodiment, each of the first lower metal layer BML1, the second lower metal layer BML2, and the third lower metal layer BML3 may include a conductive material. For example, the conductive material may include molybdenum Mo, copper Cu, aluminum Al, titanium Ti, or the like. These may be used alone or in combination.

The buffer layer BF may be disposed on the first substrate SUB1. For example, the buffer layer BF may cover the first lower metal layer BML1, the second lower metal layer BML2, and the third lower metal layer BML3 on the first substrate SUB1. The buffer layer BF may prevent metal atoms or impurities from diffusing into the transistors from the first substrate SUB1. The buffer layer BF may improve the flatness of the surface of the first substrate SUB1 when the surface of the first substrate SUB1 is not uniform. In an embodiment, the buffer layer BF may include an inorganic insulating material. For example, the inorganic insulating material may include silicon oxide, silicon nitride, silicon oxynitride, or the like. These may be used alone or in combination.

The first active layer ACT1, the second active layer ACT2, and the third active layer ACT3 may be disposed on the buffer layer BF. In an embodiment, the first active layer ACT1 may be disposed in the first pixel area PA1. In an embodiment, the second active layer ACT2 may be disposed in the second pixel area PA2. In an embodiment, the third active layer ACT3 may be disposed in the third pixel area PA3.

In an embodiment, each of the first active layer ACT1, the second active layer ACT2, and the third active layer ACT3 may include a metal oxide semiconductor, an inorganic semiconductor (e.g., amorphous silicon, poly silicon), or an organic semiconductor. However, the materials included in each of the first active layer ACT1, the second active layer ACT2, and the third active layer ACT3 according to embodiments of the present disclosure may not be necessarily limited thereto.

The first active layer ACT1 may include a first source area, a first drain area, and a first channel area disposed between the first source area and the first drain area. The second active layer ACT2 may include a second source area, a second drain area, and a second channel area disposed between the second source area and the second drain area. The third active layer ACT3 may include a third source area, a third drain area, and a third channel area disposed between the third source area and the third drain area.

The first gate insulating layer GIL1 may be disposed on the first active layer ACT1. In an embodiment, the first gate insulating layer GIL1 may overlap the first active layer ACT1 in a plan view. The second gate insulating layer GIL2 may be disposed on the second active layer ACT2. In an embodiment, the second gate insulating layer GIL2 may overlap the second active layer ACT2 in a plan view. The third gate insulating layer GIL3 may be disposed on the third active layer ACT3. In an embodiment, the third gate insulating layer GIL3 may overlap the third active layer ACT3 in a plan view. In an embodiment, each of the first gate insulating layer GIL1, the second gate insulating layer GIL2, and the third gate insulating layer GIL3 may include an inorganic insulating material.

The first gate electrode GE1 may be disposed on the first gate insulating layer GIL1. In an embodiment, the first gate electrode GE1 may overlap the first active layer ACT1 in a plan view. For example, the first gate electrode GE1 may overlap the first channel area of the first active layer ACT1 in a plan view. The second gate electrode GE2 may be disposed on the second gate insulating layer GIL2. In an embodiment, the second gate electrode GE2 may overlap the second active layer ACT2 in a plan view. For example, the second gate electrode GE2 may overlap the second channel area of the second active layer ACT2 in a plan view. The third gate electrode GE3 may be disposed on the third gate insulating layer GIL3. In an embodiment, the third gate electrode GE3 may overlap the third active layer ACT3 in a plan view. For example, the third gate electrode GE3 may overlap the third channel area of the third active layer ACT3 in a plan view.

Each of the first gate electrode GE1, the second gate electrode GE2, and the third gate electrode GE3 may include a metal, an alloy metal nitride, a conductive metal oxide, a transparent conductive material, and the like. For example, the metal may include silver Ag, molybdenum Mo, aluminum Al, tungsten W, copper Cu, nickel Ni, chromium Cr, titanium Ti, tantalum Ta, platinum Pt, scandium Sc, and the like. These may be used alone or in combination with each other.

For example, the conductive metal oxide may include indium tin oxide ITO, indium zinc oxide IZO, and the like. These may be used alone or in combination with each other. For example, the metal nitride may include aluminum nitride AlNₓ, tungsten nitride WNₓ, chromium nitride CrNₓ, and the like. These may be used alone or in combination with each other.

In an embodiment, the first gate electrode GE1, the second gate electrode GE2, and the third gate electrode GE3 may be disposed in a same layer. For example, the first gate electrode GE1, the second gate electrode GE2, and the third gate electrode GE3 may include the same material. For example, the first gate electrode GE1, the second gate electrode GE2, and the third gate electrode GE3 may be formed through the same process.

In an embodiment, each of the first gate electrode GE1, the second gate electrode GE2, and the third gate electrode GE3 may have a single-layer structure. In another embodiment, each of the first gate electrode GE1, the second gate electrode GE2, and the third gate electrode GE3 may have a multi-layer structure in which at least two or more conductive layers are stacked.

The first insulating layer IL1 may be disposed on the buffer layer BF. For example, the first insulating layer IL1 may cover the first gate electrode GE1, the second gate electrode GE2, and the third gate electrode GE3 on the buffer layer BF. In an embodiment, the first insulating layer IL1 may include an inorganic insulating material or an organic insulating material. In an embodiment, the first insulating layer IL1 may provide a substantially flat upper surface. However, the first insulating layer IL1 according to embodiments of the present disclosure may not be necessarily limited thereto, and the first insulating layer IL1 may have a substantially uniform thickness along profiles of each of the first gate electrode GE1, the second gate electrode GE2, and the third gate electrode GE3.

The first source electrode SE1 and the first drain electrode DE1 may be disposed on the first insulating layer IL1. In an embodiment, the first source electrode SE1 and the first drain electrode DE1 may be electrically connected to the first active layer ACT1. For example, the first source electrode SE1 may contact the first source area through a contact hole penetrating the first insulating layer IL1 in a thickness direction (e.g., the third direction DR3). In addition, the first source electrode SE1 may contact the first lower metal layer BML1 through a contact hole penetrating the first insulating layer IL1 and the buffer layer BF in a thickness direction (e.g., the third direction DR3). For example, the first drain electrode DE1 may contact the first drain area through a contact hole penetrating the first insulating layer IL1 in a thickness direction. However, the first source electrode SE1 and the first drain electrode DE1 according to embodiments of the present disclosure may not be necessarily limited thereto. For example, the first source electrode SE1 may not contact the first lower metal layer BML1, and the first drain electrode DE1 may contact the first lower metal layer BML1 through a contact hole penetrating the first insulating layer IL1 and the buffer layer BF in a thickness direction.

The second source electrode SE2 and the second drain electrode DE2 may be disposed on the first insulating layer IL1. In an embodiment, the second source electrode SE2 and the second drain electrode DE2 may be electrically connected to the second active layer ACT2. For example, the second source electrode SE2 may contact the second source area through a contact hole penetrating the first insulating layer IL1 in a thickness direction. In addition, the second source electrode SE2 may contact the second lower metal layer BML2 through a contact hole penetrating the first insulating layer IL1 and the buffer layer BF in a thickness direction. For example, the second drain electrode DE2 may contact the second drain area through a contact hole penetrating the first insulating layer IL1 in a thickness direction. However, the second source electrode SE2 and the second drain electrode DE2 according to embodiments of the present disclosure may be not necessarily limited thereto. For example, the second source electrode SE2 may not contact the second lower metal layer BML2, and the second drain electrode DE2 may contact the second lower metal layer BML2 through a contact hole penetrating the first insulating layer IL1 and the buffer layer BF in a thickness direction.

The third source electrode SE3 and the third drain electrode DE3 may be disposed on the first insulating layer IL1. The third source electrode SE3 and the third drain electrode DE3 may be disposed on the first insulating layer IL1. In an embodiment, the third source electrode SE3 and the third drain electrode DE3 may be electrically connected to the second active layer ACT2. For example, the third source electrode SE3 may contact the third source area through a contact hole penetrating the first insulating layer IL1 in a thickness direction. In addition, the third source electrode SE3 may contact the third lower metal layer BML3 through a contact hole penetrating the first insulating layer IL1 and the buffer layer BF in a thickness direction. For example, the third drain electrode DE3 may contact the third drain area through a contact hole penetrating the first insulating layer IL1 in a thickness direction. However, the third source electrode SE3 and the third drain electrode DE3 according to embodiments of the present disclosure may not be necessarily limited thereto. For example, the third source electrode SE3 may not contact the third lower metal layer BML3, and the third drain electrode DE3 may contact the third lower metal layer BML3 through a contact hole penetrating the first insulating layer IL1 and the buffer layer BF in a thickness direction.

In an embodiment, each of the first source electrode SE1, the first drain electrode DE1, the second source electrode SE2, the second drain electrode DE2, the third source electrode SE3, and the third drain electrode DE3 may include a conductive material. In an embodiment, each of the first source electrode SE1, the first drain electrode DE1, the second source electrode SE2, the second drain electrode DE2, the third source electrode SE3, and the third drain electrode DE3 may have a single-layer structure. In another embodiment, in an embodiment, each of the first source electrode SE1, the first drain electrode DE1, the second source electrode SE2, the second drain electrode DE2, the third source electrode SE3, and the third drain electrode DE3 may have a multilayer structure in which at least two or more conductive layers are stacked.

The second insulating layer IL2 may be disposed on the first insulating layer IL1. For example, the second insulating layer IL2 may cover the first source electrode SE1, the first drain electrode DE1, the second source electrode SE2, the second drain electrode DE2, the third source electrode SE3, and the third drain electrode DE3 on the first insulating layer IL1. In an embodiment, the second insulating layer IL2 may include an inorganic insulating material or an organic insulating material.

In an embodiment, the second insulating layer IL2 may provide a substantially flat upper surface. However, the second insulating layer IL2 according to embodiments of the present disclosure may not be necessarily limited thereto, and the second insulating layer IL2 may have a substantially uniform thickness along the profiles of each of the first source electrode SE1, the first drain electrode DE1, the second source electrode SE2, the second drain electrode DE2, the third source electrode SE3, and the third drain electrode DE3.

The third insulating layer IL3 may be disposed on the second insulating layer IL2. In an embodiment, the third insulating layer IL3 may include an organic insulating material such as polyimide. In an embodiment, the third insulating layer IL3 may provide a substantially flat upper surface.

The first pixel electrode PE1, the second pixel electrode PE2, and the third pixel electrode PE3 may be disposed on the third insulating layer IL3. In an embodiment, the first pixel electrode PE1 may be disposed in the first pixel area PA1. In an embodiment, the second pixel electrode PE2 may be disposed in the second pixel area PA2. In an embodiment, the third pixel electrode PE3 may be disposed in the third pixel area PA3.

In an embodiment, the first pixel electrode PE1 may be electrically connected to the first source electrode SE1. For example, the first lower transparent electrode LTE1 included in the first pixel electrode PE1 may contact the first source electrode SE1 through the first contact hole CNT1 penetrating the second insulating layer IL2 and the third insulating layer IL3 in the thickness direction (e.g., the third direction DR3). However, the first pixel electrode PE1 according to embodiments of the present disclosure may not be necessarily limited thereto, and the first pixel electrode PE1 may contact the first drain electrode DE1 through a contact hole penetrating the second insulating layer IL2 and the third insulating layer IL3 in the thickness direction.

The first lower transparent electrode LTE1 may be disposed on the third insulating layer IL3. In an embodiment, the first lower transparent electrode LTE1 may include a transparent material. For example, the transparent material may include indium tin oxide. However, the material included in the first lower transparent electrode LTE1 according to embodiments of the present disclosure may not be necessarily limited thereto.

The first reflection electrode RE1 may be disposed on the first lower transparent electrode LTE1. In an embodiment, the first reflection electrode RE1 may include a metal material that reflects light. For example, the first reflection electrode RE1 may include silver, titanium, and the like. These may be used alone or in combination with each other. However, the material included in the first reflection electrode RE1 according to embodiments of the present disclosure is not necessarily limited thereto.

The first upper transparent electrode UTE1 may be disposed on the first reflection electrode RE1. In an embodiment, the first upper transparent electrode UTE1 may include a transparent material. For example, the transparent material may include indium tin oxide. However, the material included in the first upper transparent electrode UTE1 according to embodiments of the present disclosure is not necessarily limited thereto. In an embodiment, the first lower transparent electrode LTE1 and the first upper transparent electrode UTE1 may include the same material.

The first thickness compensation layer TCL1 may be disposed on the first upper transparent electrode UTE1. In an embodiment, the first thickness compensation layer TCL1 may include a transparent material. For example, the transparent material may include indium zinc oxide. However, the material included in the first thickness compensation layer TCL1 according to embodiments of the present disclosure may not be necessarily limited thereto. In an embodiment, the first thickness compensation layer TCL1 may directly contact the first upper transparent electrode UTE1.

In an embodiment, a weight ratio wt % of indium (In) and zinc (Zn) included in the first thickness compensation layer TCL1 may be about 6:4 to about 8:2. Preferably, the weight ratio of indium (In) and zinc (Zn) included in the first thickness compensation layer TCL1 may be about 6.5:3.5 to about 7.5:2.5. More preferably, the weight ratio of indium (In) and zinc (Zn) included in the first thickness compensation layer TCL1 may be about 7:3.

In an embodiment, the first thickness compensation layer TCL1 and the first lower transparent electrode LTE1 may include a different material from each other. In an embodiment, the first thickness compensation layer TCL1 and the first upper transparent electrode UTE1 may include a different material from each other.

In an embodiment, in a plan view, the first thickness compensation layer TCL1 may be less than or equal to the first upper transparent electrode UTE1. For example, a length of the first thickness compensation layer TCL1 in the first direction DR1 may be less than or equal to a length of the first upper transparent electrode UTE1 in the first direction DR1. For example, a length of the first thickness compensation layer TCL1 in the second direction DR2 may be less than or equal to ae length of the first upper transparent electrode UTE1 in the second direction DR2.

The second thickness compensation layer TCL2 may be disposed on the first thickness compensation layer TCL1. In an embodiment, the second thickness compensation layer TCL2 may include a transparent material. For example, the transparent material may include indium tin oxide. However, the material included in the second thickness compensation layer TCL2 according to embodiments of the disclosure may not be necessarily limited thereto. In an embodiment, the second thickness compensation layer TCL2 may directly contact the first thickness compensation layer TCL1.

In an embodiment, the second thickness compensation layer TCL2 and the first lower transparent electrode LTE1 may include the same material. In an embodiment, the second thickness compensation layer TCL2 and the first upper transparent electrode UTE1 may include a same material.

In an embodiment, in a plan view, the second thickness compensation layer TCL2 may have a size less than or equal to the first thickness compensation layer TCL1. For example, a length of the second thickness compensation layer TCL2 in the first direction DR1 may be less than or equal to a length of the first thickness compensation layer TCL1 in the first direction DR1. For example, a length of the second thickness compensation layer TCL2 in the second direction DR2 may be less than or equal to a length of the first thickness compensation layer TCL1 in the second direction DR2.

In an embodiment, the second thickness compensation layer TCL2 may include a central portion and an edge portion. For example, the central portion of the second thickness compensation layer TCL2 may be parallel to a side of the first thickness compensation layer TCL1 facing the common electrode CE. For example, the edge portion of the second thickness compensation layer TCL2 may have an inclination angle θ1 with respect to a surface of the first thickness compensation layer TCL1.

In an embodiment, the second thickness compensation layer TCL2 may directly contact the side surface of the pixel defining layer PDL. For example, the edge portion of the second thickness compensation layer TCL2 may directly contact both side surfaces of the pixel defining layer PDL. Specifically, the edge portion of the second thickness compensation layer TCL2 may extend from the center portion of the second thickness compensation layer TCL2 and may have an inclination angle θ1 with the center portion of the second thickness compensation layer TCL2 and may directly contact the side surface of the pixel defining layer PDL.

In an embodiment, the inclination angle θ1 may be about 5°to about 30°. However, a range of the inclination angle θ1 according to embodiments of the disclosure may vary depending on the pixel defining layer PDL and may not be necessarily limited thereto.

In an embodiment, a sum of the thicknesses of the first upper transparent electrode UTE1, the first thickness compensation layer TCL1, and the second thickness compensation layer TCL2 may be from about 600 Å to about 1500 Å. Preferably, the sum of the thicknesses of the first upper transparent electrode UTE1, the first thickness compensation layer TCL1, and the second thickness compensation layer TCL2 may be from about 800 Å to about 1200 Å.

In an embodiment, the second pixel electrode PE2 may be electrically connected to the second source electrode SE2. For example, the second lower transparent electrode LTE2 included in the second pixel electrode PE2 may contact the second source electrode SE2 through the second contact hole CNT2 penetrating the second insulating layer IL2 and the third insulating layer IL3 in the thickness direction. However, the second pixel electrode PE2 according to embodiments of the disclosure may not be necessarily limited thereto, and the second pixel electrode PE2 may contact the second drain electrode DE2 through a contact hole penetrating the second insulating layer IL2 and the third insulating layer IL3 in a thickness direction.

The second lower transparent electrode LTE2 may be disposed on the third insulating layer IL3. In an embodiment, the second lower transparent electrode LTE2 may include a transparent material. For example, the transparent material may include indium tin oxide. However, the material included in the second lower transparent electrode LTE2 according to embodiments of the disclosure may not be necessarily limited thereto.

In an embodiment, the thickness of the second lower transparent electrode LTE2 may be substantially equal to the thickness of the first lower transparent electrode LTE1. For example, the first lower transparent electrode LTE1 and the second lower transparent electrode LTE2 may include a same material. For example, the first lower transparent electrode LTE1 and the second lower transparent electrode LTE2 may be formed through a same process.

The second reflection electrode RE2 may be disposed on the second lower transparent electrode LTE2. In an embodiment, the second reflection electrode RE2 may include a metal material that reflects light. For example, the second reflection electrode RE2 may include silver, titanium, and the like. These may be used alone or in combination. However, materials included in the second reflection electrode RE2 according to embodiments of the disclosure may not be necessarily limited thereto.

In an embodiment, a thickness of the second reflection electrode RE2 may be substantially equal to a thickness of the first reflection electrode RE1. For example, the first reflection electrode RE1 and the second reflection electrode RE2 may include a same material. For example, the first reflection electrode RE1 and the second reflection electrode RE2 may be formed through a same process.

The second upper transparent electrode UTE2 may be disposed on the second reflection electrode RE2. In an embodiment, the second upper transparent electrode UTE2 may include a transparent material. For example, the transparent material may include indium tin oxide. However, the material included in the second upper transparent electrode UTE2 according to embodiments of the disclosure is not necessarily limited thereto. In an embodiment, the second lower transparent electrode LTE2 and the second upper transparent electrode UTE2 may include the same material.

In an embodiment, a thickness of the second upper transparent electrode UTE2 may be substantially equal to a thickness of the first upper transparent electrode UTE1. For example, the first upper transparent electrode UTE1 and the second upper transparent electrode UTE2 may include the same material. For example, the first upper transparent electrode UTE1 and the second upper transparent electrode UTE2 may be formed through the same process.

In an embodiment, a thickness of the second upper transparent electrode UTE2 may be about 100 Å to about 300 Å. Preferably, the thickness of the second upper transparent electrode UTE2 may be about 120 Å to about 200 Å.

The dummy pattern DMP may be disposed on the second upper transparent electrode UTE2. For example, the dummy pattern DMP may be disposed on an edge portion of the second upper transparent electrode UTE2. In an embodiment, the dummy pattern DMP may directly contact the edge portion of the second upper transparent electrode UTE2.

In an embodiment, the thickness of the dummy pattern DMP may be substantially equal to the thickness of the first thickness compensation layer TCL1. For example, the first thickness compensation layer TCL1 and the dummy pattern DMP may include a same material. For example, the first thickness compensation layer TCL1 and the dummy pattern DMP may be formed through a same process.

In an embodiment, the dummy pattern DMP may overlap the pixel defining layer PDL in a plan view. In an embodiment, at least a portion of the dummy pattern DMP may be surrounded by the pixel defining layer PDL.

In an embodiment, the third pixel electrode PE3 may be electrically connected to the third source electrode SE3. For example, the third lower transparent electrode LTE3 included in the third pixel electrode PE3 may be in contact with the third source electrode SE3 through the third contact hole CNT3 penetrating the second insulating layer IL2 and the third insulating layer IL3 in a thickness direction. However, the third pixel electrode PE3 according to embodiments of the present disclosure may not be necessarily limited thereto, and the third pixel electrode PE3 may contact the third drain electrode DE3 through a contact hole penetrating the second insulating layer IL2 and the third insulating layer IL3 in the thickness direction.

The third lower transparent electrode LTE3 may be disposed on the third insulating layer IL3. In an embodiment, the third lower transparent electrode LTE3 may include a transparent material. For example, the transparent material may include indium tin oxide. However, the material included in the third lower transparent electrode LTE3 according to embodiments of the present disclosure is not necessarily limited thereto.

In an embodiment, a thickness of the third lower transparent electrode LTE3 may be substantially equal to a thickness of the first lower transparent electrode LTE1. For example, the first lower transparent electrode LTE1 and the third lower transparent electrode LTE3 may include a same material. For example, the first lower transparent electrode LTE1 and the third lower transparent electrode LTE3 may be formed through a same process.

The third reflection electrode RE3 may be disposed on the third lower transparent electrode LTE3. In an embodiment, the third reflection electrode RE3 may include a metal material that reflects light. For example, the third reflection electrode RE3 may include silver, titanium, and the like. These may be used alone or in combination. However, materials included in the third reflection electrode RE3 according to embodiments of the present disclosure may not be necessarily limited thereto.

In an embodiment, the thickness of the third reflection electrode RE3 may be substantially equal to the thickness of the first reflection electrode RE1. For example, the first reflection electrode RE1 and the third reflection electrode RE3 may include a same material. For example, the first reflection electrode RE1 and the third reflection electrode RE3 may be formed through a same process.

The third upper transparent electrode UTE3 may be disposed on the third reflection electrode RE3. In an embodiment, the third upper transparent electrode UTE3 may include a transparent material. For example, the transparent material may include indium tin oxide. However, the material included in the third upper transparent electrode UTE3 according to embodiments of the present disclosure may not be necessarily limited thereto. In an embodiment, the third lower transparent electrode LTE3 and the third upper transparent electrode UTE3 may include a same material.

In an embodiment, a thickness of the third upper transparent electrode UTE3 may be substantially equal to a thickness of the first upper transparent electrode UTE1. For example, the first upper transparent electrode UTE1 and the third upper transparent electrode UTE3 may include the same material. For example, the first upper transparent electrode UTE1 and the third upper transparent electrode UTE3 may be formed through a same process.

The third thickness compensation layer TCL3 may be disposed on the third upper transparent electrode UTE3. In an embodiment, the third thickness compensation layer TCL3 may include a transparent material. For example, the transparent material may include indium tin oxide. However, the material included in the third thickness compensation layer TCL3 according to embodiments of the present disclosure may not be necessarily limited thereto. In an embodiment, the third thickness compensation layer TCL3 may directly contact the third upper transparent electrode UTE3.

In an embodiment, the third thickness compensation layer TCL3 and the third lower transparent electrode LTE3 may include a same material. In an embodiment, the third thickness compensation layer TCL3 and the third upper transparent electrode UTE3 may include a same material.

In an embodiment, in a plan view, a size of the third thickness compensation layer TCL3 may be less than a size of the third upper transparent electrode UTE3. For example, a length of the third thickness compensation layer TCL3 in the first direction DR1 may be less than a length of the third upper transparent electrode UTE3 in the first direction DR1. For example, a length of the third thickness compensation layer TCL3 in the second direction DR2 may be less than a length of the third upper transparent electrode UTE3 in the second direction DR2.

In an embodiment, the third thickness compensation layer TCL3 may include a central portion and an edge portion. For example, the central portion of the second thickness compensation layer TCL3 may be parallel to a surface facing the common electrode CE of the third upper transparent electrode UTE3. For example, the edge portion of the third thickness compensation layer TCL3 may have an angle of inclination with respect to the surface of the third upper transparent electrode UTE3.

In an embodiment, the third thickness compensation layer TCL3 may directly contact a side surface of the pixel defining layer PDL. For example, the edge portion of the third thickness compensation layer TCL3 may directly contact both side surfaces of the pixel defining layer PDL. Specifically, the edge portion of the third thickness compensation layer TCL3 may extend from the center portion of the third thickness compensation layer TCL3 and may have an inclination angle θ2 with the center portion of the third thickness compensation layer TCL3 and may directly contact the side surface of the pixel defining layer PDL.

In an embodiment, the inclination angle θ2 may be about 5°to about 30°. However, a range of the inclination angle θ2 according to embodiments of the present disclosure may vary depending on the pixel defining layer PDL and may not be necessarily limited thereto.

In an embodiment, a thickness of the third thickness compensation layer TCL3 may be substantially equal to a thickness of the second thickness compensation layer TCL2. In an embodiment, the second thickness compensation layer TCL2 and the third thickness compensation layer TCL3 may include the same material. In an embodiment, the second thickness compensation layer TCL2 and the third thickness compensation layer TCL3 may be formed through a same process.

In an embodiment, a sum of the thicknesses of the third upper transparent electrode UTE3 and the third thickness compensation layer TCL3 may be about 400 Å to about 1000 Å. Preferably, the sum of the thicknesses of the third upper transparent electrode UTE3 and the third thickness compensation layer TCL3 may be about 600 Å to about 800 Å.

In an embodiment, a sum of the thicknesses of the first upper transparent electrode UTE1, the first thickness compensation layer TCL1, and the second thickness compensation layer TCL2 may be greater than a sum of the thicknesses of the third upper transparent electrode UTE3 and the third thickness compensation layer TCL3.

In an embodiment, a sum of the thicknesses of the first upper transparent electrode UTE1, the first thickness compensation layer TCL1, and the second thickness compensation layer TCL2 may be greater than a thickness of the second upper transparent electrode UTE2.

In an embodiment, a thickness of the second upper transparent electrode UTE2 may be less than a sum of the thicknesses of the third upper transparent electrode UTE3 and the third thickness compensation layer TCL3.

The pixel defining layer PDL may be disposed on the third insulating layer IL3. In an embodiment, the pixel defining layer PDL may cover a portion of each of the first pixel electrode PE1, the second pixel electrode PE2, and the third pixel electrode PE3 on the third insulating layer IL3. In an embodiment, the pixel defining layer PDL may have a first hole defined therein that exposes (or extends to) one surface (e.g., an upper surface) of the second thickness compensation layer TCL2. Specifically, the pixel defining layer PDL may cover an edge portion of each of the first lower transparent electrode LTE1, the first reflection electrode RE1, the first upper transparent electrode UTE1, and the first thickness compensation layer TCL1. In addition, the first hole of the pixel defining layer PDL may extend from the second thickness compensation layer TCL2 to a center of each of the first thickness compensation layer TCL1, the first upper transparent electrode UTE1, the first reflection electrode RE1, and the first lower transparent electrode LTE1 in an order of the first thickness compensation layer TCL1, the first upper transparent electrode UTE1, the first reflection electrode RE1, and the first lower transparent electrode LTE1.

For example, a second hole exposing a portion of the second pixel electrode PE2 may be defined in the pixel defining layer PDL. Specifically, the pixel defining layer PDL may cover an edge portion of each of the second lower transparent electrode LTE2, the second reflection electrode RE2, and the second upper transparent electrode UTE2. In addition, the second hole of the pixel defining layer PDL may extend from the second upper transparent electrode UTE2 to the center of each of the second upper transparent electrode UTE2, the second reflection electrode RE2 and the second lower transparent electrode LTE2 in an order of the second reflection electrode RE2 and the second lower transparent electrode LTE2.

For example, a third hole exposing a side (e.g., the upper side) of the third thickness compensation layer TCL3 may be defined in the pixel defining layer PDL. Specifically, the pixel defining layer PDL may cover an edge portion of each of the third lower transparent electrode LTE3, the second reflection electrode RE3 and the third upper transparent electrode UTE3. In addition, the third hole of the pixel defining layer PDL may extend from the third thickness compensation layer TCL3 to the center of each of the third upper transparent electrode UTE3, the third reflection electrode RE3, and the third lower transparent electrode LTE3 in an order of the third upper transparent electrode UTE3, the third reflection electrode RE3, and the third lower transparent electrode LTE3.

In an embodiment, the pixel defining layer PDL may include an organic insulating material such as polyimide. In an embodiment, the pixel defining layer PDL may further include a light-blocking material. However, materials included in the pixel defining layer PDL according to the embodiments of the present disclosure may not be necessarily limited thereto.

The light-emitting layer EL may be disposed on the pixel defining layer PDL. In an embodiment, the light-emitting layer EL may be in contact with the upper portions of each of the second thickness compensation layer TCL2, the second upper transparent electrode UTE2, and the third thickness compensation layer TCL3 on the pixel defining layer PDL. In an embodiment, the light-emitting layer EL may be disposed across the first pixel electrode PE1, the second pixel electrode PE2, the third pixel electrode PE3, and the pixel defining layer PDL within the pixel area DA. In other words, the light-emitting layer EL may be disposed across the first pixel area PA1, the second pixel area PA2, and the third pixel area PA3.

However, other light-emitting layers EL in embodiments of the present disclosure may not be necessarily limited thereto. For example, the light-emitting layer EL may include a first light-emitting layer, a second light-emitting layer, and a third light-emitting layer that are disconnected from each other in the cross section, the first light-emitting layer may fill the first hole of the pixel defining layer PDL and be disposed on the second thickness compensation layer TCL2, the second light-emitting layer may fill the second hole of the pixel defining layer PDL and may be disposed on the second upper transparent electrode UTE2, and the third light-emitting layer may fill the third hole of the pixel defining layer PDL and may be disposed on the third thickness compensation layer TCL3.

In an embodiment, the light-emitting layer EL may include an organic light-emitting material. However, the light-emitting layer EL according to embodiments of the present disclosure is not necessarily limited thereto, and the light-emitting layer EL may include quantum dots, or the like.

The common electrode CE may be disposed on the light-emitting layer EL. For example, the common electrode CE may extend in the first direction DR1 and the second direction DR2 within the display area DA on the light-emitting layer EL. In other words, the common electrode CE may be disposed across the first pixel area PA1, the second pixel area PA2, and the third pixel area PA3.

In an embodiment, a side of the common electrode CE may have a first height in the first pixel area PA1 with respect to the first substrate SUB1, and may have a second height different from the first height in the second pixel area PA2. For example, the first height may be greater than the second height. Specifically, the height of the side of the common electrode CE may mean the shortest distance that the side is spaced from the first substrate SUB1.

In an embodiment, the side of the common electrode CE may have a third height different from the first height and the second height in the third pixel area PA3. For example, the third height may be less than the first height and larger than the second height.

In an embodiment, a height of the side of the common electrode CE in the second pixel area PA2 based on the first substrate SUB1 may be different from a height of the side of the common electrode CE in the third pixel area PA3 based on the first substrate SUB1.

Specifically, the first thickness compensation layer TCL1 and the second thickness compensation layer TCL2 may be disposed on the first reflection electrode RE1 included in the first pixel electrode PE1, and the thickness compensation layer may not be disposed on the second reflection electrode RE2 included in the second pixel electrode PE2. In addition, two thickness compensation layers (e.g., the first thickness compensation layer TCL1 and the second thickness compensation layer TCL2) may be disposed on the first reflection electrode RE1, and one thickness compensation layer (e.g., the third thickness compensation layer TCL3 may be included on the third reflection electrode RE3 included in the third pixel electrode PE3.

Accordingly, the height of the common electrode CE located in the first pixel area PA1 from the upper surface of the third insulating layer IL3 may be greater than the height of the common electrode CE located in the second pixel area PA2 from the upper surface of the third insulating layer IL3. In addition, the height of the common electrode CE located in the first pixel area PA1 from the upper surface of the third insulating layer IL3 may be greater than the height of the common electrode CE located in the third pixel area PA3 from the upper surface of the third insulating layer IL3. The height of the common electrode CE disposed in the third pixel area PA3 from the upper surface of the third insulating layer IL3 may be greater than the height of the common electrode CE disposed in the second pixel area PA2 from the upper surface of the third insulating layer IL3.

In other words, a difference in the height of the common electrode CE may occur depending on the difference in the number of thickness compensation layers (e.g., the first thickness compensation layer TCL1, the second thickness compensation layer TCL2, and the third thickness compensation layer TCL3) disposed between the reflection electrode (e.g., the first reflection electrode RE1), the second reflection electrode RE2, and the third reflection electrode RE3) and the light-emitting layer on a cross-sectional view, and each of a first resonance distance RL1, a second resonance distance RL2, and a third resonance distance RL3 may be adjusted to correspond to the wavelength of the emitted light.

In an embodiment, light of the first color emitted from the light-emitting layer EL disposed in the first pixel area PA1 may resonate between the first pixel electrode PE1 and the common electrode CE. Specifically, the light of the first color emitted from the light-emitting layer EL disposed in the first pixel area PA1 may resonate between the first reflection electrode RE1 and the common electrode CE.

In an embodiment, light of the second color emitted from the light-emitting layer EL disposed in the second pixel area PA2 may resonate between the second pixel electrode PE2 and the common electrode CE. Specifically, the light of the second color emitted from the light-emitting layer EL disposed in the second pixel area PA2 may resonate between the second reflection electrode RE2 and the common electrode CE.

In an embodiment, light of the third color emitted from the light-emitting layer EL disposed in the third pixel area PA3 may resonate between the third pixel electrode PE3 and the common electrode CE. Specifically, the light of the third color emitted from the light-emitting layer EL disposed in the third pixel area PA3 may resonate between the third reflection electrode RE3 and the common electrode CE.

In an embodiment, the first resonant distance RL1 may be defined as a shortest distance between the first reflection electrode RE1 and the common electrode CE. For example, the first resonant distance RL1 may have a value for increasing light-emitting efficiency of the light of the first color emitted from the light-emitting layer EL disposed in the first pixel area PA1. In an embodiment, the first resonant distance RL1 may satisfy a following [Formula 1].

$$RL = ( λ / 2 ) \times N \qquad [ Formula 1 ]$$

Here, RL is a resonance distance, λ is a median wavelength of light emitted from the light-emitting layer EL, and N is a natural number.

Referring to the [Formula 1], when the light of the first color is red light, the wavelength may be about 610 nm to about 700 nm. Accordingly, the λ may be about 655 nm, which is the median value of the wavelength of the light of the first color, and the resonance distance RL may be an integer multiple of about 377.5 nm, which is half the median value of the wavelength of the light of the first color. The value of the resonance distance RL calculated for the light of the first color may be the first resonance distance RL1.

Accordingly, when a portion of the light of the first color emitted from the light-emitting layer EL disposed in the first pixel area PA1 is incident toward the first reflection electrode RE1 and reflected from the first reflection electrode RE1, and another portion of the light of the first color travels toward the common electrode CE, a portion of the light of the first color and another portion of the light of the first color constructively interfere with each other, so that the light-emitting efficiency of the light of the first color may be improved.

In an embodiment, the second resonance distance RL2 may be defined as the shortest distance between the second reflection electrode RE2 and the common electrode CE. For example, the second resonance distance RL2 may have a value for increasing the light-emitting efficiency of the light of the second color emitted from the light-emitting layer EL disposed in the second pixel area PA2. In an embodiment, the second resonance distance RL2 may satisfy the [Formula 1].

Referring to the [Formula 1], if the light of the second color is green, the wavelength is about 500 nm to about 570 nm, so the λ is about 535 nm, which is the median value of the wavelength of the light of the second color, and the resonance distance RL may be an integer multiple of about 267.5 nm, which is half the median value of the wavelength of the light of the second color. The value of the resonance distance RL calculated for the light of the second color may be the second resonance distance RL2.

Accordingly, when a portion of the light of the second color emitted from the light-emitting layer EL disposed in the second pixel area PA2 is incident toward the second reflection electrode RE2 and reflected from the second reflection electrode RE2, and another portion of the light of the second color travels toward the common electrode CE, the light-emitting efficiency of the light of the second color may be improved by constructively interfering with a portion of the light of the second color and another portion of the light of the second color.

In an embodiment, the third resonant distance RL3 may be defined as the shortest distance between the third reflection electrode RE3 and the common electrode CE. For example, the third resonant distance RL3 may have a value for improving the light-emitting efficiency of the light of the third color emitted from the light-emitting layer EL disposed in the third pixel area PA3. In an embodiment, the third resonant distance RL3 may satisfy the above [Formula 1].

Referring to the [Formula 1], if the light of the third color is blue, the wavelength is about 450 nm to about 500 nm, so the λ is about 475 nm, which is the median of the wavelength of the light of the third color, and the resonance distance RL may be an integer multiple of about 237.5 nm, which is half of the median of the wavelength of the light of the third color. The value of the resonance distance RL calculated for the light of the third color may be the third resonance distance RL3.

Accordingly, when a portion of the light of the third color emitted from the light-emitting layer EL disposed in the third pixel area PA3 is incident toward the third reflection electrode RE3 and reflected from the third reflection electrode RE3, and another portion of the light of the third color travels toward the common electrode CE, a portion of the light of the third color and another portion of the light of the third color constructively interfere with each other, so that the light-emitting efficiency of the light of the third color may be improved.

In an embodiment, the first resonant distance RL1 may be greater than the second resonant distance RL2. In an embodiment, the first resonant distance RL1 may be greater than the third resonant distance RL3. In an embodiment, the second resonant distance RL2 may be less than the third resonant distance RL3.

A thin film encapsulation layer TFE may be disposed on a common electrode CE. The thin film encapsulation layer TFE may include at least one inorganic encapsulation layer and at least one organic encapsulation layer. In an embodiment, the inorganic encapsulation layer and the organic encapsulation layer may be alternately disposed. For example, the organic encapsulation layer may include a polymer cured material such as polyacrylate, epoxy resin, silicone resin, and the like. For example, the inorganic encapsulation layer may include silicon oxide, silicon nitride, silicon carbide, aluminum oxide, tantalum oxide, hafnium oxide, zirconium oxide, titanium oxide, and the like.

The thin film encapsulation layer TFE may prevent impurities from entering the first light-emitting element EE1, the second light-emitting element EE2, and the third light-emitting element EE3. The first protective layer PRL1 may be disposed on the thin film encapsulation layer TFE. The first protective layer PRL1 may prevent impurities from flowing into the first color conversion layer CCL1, the second color conversion layer CCL2, and the light transmitting layer LTL. For example, the first protective layer PRL1 may include an inorganic material such as silicon oxide, silicon nitride, silicon oxynitride, and the like. These may be used alone or in combination with each other. However, the materials included in the first protective layer PRL1 according to embodiments of the present disclosure may not be necessarily limited thereto.

The first color conversion layer CCL1, the second color conversion layer CCL2, and the light transmitting layer LTL may be disposed on the first protective layer PRL1. In an embodiment, the first color conversion layer CCL1, the second color conversion layer CCL2, and the light-transmitting layer LTL may be spaced apart from each other in a plan view. A light-blocking member BL may be disposed between the first color conversion layer CCL1, the second color conversion layer CCL2, and the light-transmitting layer LTL.

The first color conversion layer CCL1 may be disposed in the first pixel area PA1. The first color conversion layer CCL1 may include a first quantum dot, a first scattering particle, and a first photosensitive polymer that are excited by light emitted from the light-emitting layer EL and emit light of the first color.

The second color conversion layer CCL2 may be disposed in the second pixel area PA2. The second color conversion layer CCL2 may include a second quantum dot, a second scattering particle, and a second photosensitive polymer that are excited by light emitted from the light-emitting layer EL and emit light of the second color.

The light-transmitting layer LTL may be disposed in the third pixel area PA3. The light transmitting layer LTL may transmit light emitted from the light-emitting layer EL and emit the light. The light transmitting layer LTL may include a third photosensitive polymer.

The light-blocking member BL may be disposed on the first protective layer PRL1. The light-blocking member BL may partially overlap the first protective layer PRL1 in a plan view. The light-blocking member BL may block light emitted from the light-emitting layer EL from passing through the second substrate SUB2.

The light-blocking member BL may define a light-blocking area that partially overlaps each of the first pixel area PA1, the second pixel area PA2, and the third pixel area PA3 under the first color filter CF1, the second color filter CF2, and the third color filter CF3 and blocks light.

The second protective layer PRL2 may be disposed on the first color conversion layer CCL1, the second color conversion layer CCL2, the light transmitting layer LTL, and the light-blocking member BL. The second protective layer PRL2 may be disposed under the first color filter CF1, the second color filter CF2, and the third color filter CF3. In an embodiment, the second protective layer PRL2 may cover the first color filter CF1, the second color filter CF2, and the third color filter CF3. For example, the second protective layer PRL2 may be disposed along the profiles of the first color filter CF1, the second color filter CF2, and the third color filter CF3.

The second protective layer PRL2 may block external impurities to prevent contamination of the first color filter CF1, the second color filter CF2, and the third color filter CF3. For example, the second protective layer PRL2 may include an inorganic material such as silicon oxide, silicon nitride, silicon oxynitride, and the like. These may be used alone or in combination.

The first color filter CF1, the second color filter CF2, and the third color filter CF3 may be disposed on the second protective layer PRL2. Each of the first color filter CF1, the second color filter CF2, and the third color filter CF3 under the second substrate SUB2 may selectively transmit light having a specific wavelength.

In an embodiment, the first color filter CF1 may selectively transmit light of the first color. In an embodiment, the first color filter CF1 may be disposed in the first pixel area PA1 and may overlap with the light-blocking member BL in a plan view. In an embodiment, the first color filter CF1 may not be disposed in the second pixel area PA2 and the third pixel area PA3.

In an embodiment, the second color filter CF2 may selectively transmit the light of the second color. In an embodiment, the second color filter CF2 is disposed in the second pixel area PA2 and may overlap with the light-blocking member BL in a plan view. In an embodiment, the second color filter CF2 may not be disposed in the first pixel area PA1 and the third pixel area PA3.

In an embodiment, the third color filter CF3 may selectively transmit the light of the third color. In an embodiment, the third color filter CF3 is disposed in the third pixel area PA3 and may overlap with the light-blocking member BL in a plan view. In an embodiment, the third color filter CF3 may not be disposed in the first pixel area PA1 and the second pixel area PA2.

The second substrate SUB2 may be disposed on the first color filter CF1, the second color filter CF2, and the third color filter CF3. The second substrate SUB2 may transmit light emitted from the light-emitting layer EL. In an embodiment, the second substrate SUB2 may include a transparent material. For example, the second substrate SUB2 may include a transparent resin substrate. For example, the transparent resin substrate may include an insulating material such as glass or plastic. These may be used alone or in combination with each other. However, the second substrate SUB2 according to embodiments of the present disclosure may not be necessarily limited thereto, and the second substrate SUB2 may include an organic polymer material such as polycarbonate (PC), polyethylene (PE), or polypropylene (PP).

However, although the display device DD of the present disclosure is described as an organic light-emitting display device OLED in which the light-emitting layer EL includes an organic light-emitting material, other display devices DD in the embodiments of the present disclosure may not necessarily be limited thereto. For example, the display device DD may be a liquid crystal display device (LCD), a field emission display device (FED), a plasma display device (PDP), or an electrophoretic display device (EPD).

As described above, in the display device DD according to the embodiments of the present disclosure, the first reflection electrode RE1, the transparent electrode (e.g., the first upper transparent electrode UTE1) sequentially disposed on the first reflection electrode RE1, a first thickness compensation layer TCL1, and the second thickness compensation layer TCL2 may be disposed in the first pixel area PA1. In addition, the third reflection electrode RE3, a transparent electrode (e.g., the third upper transparent electrode UTE3) sequentially disposed on the third reflection electrode RE3, and a third thickness compensation layer TCL3 may be disposed in the third pixel area PA3. Accordingly, the common electrode CE disposed on the first pixel electrode PE1, the second pixel electrode PE2, and the third pixel electrode PE3 has different heights in each of the first pixel area PA1, the second pixel area PA2, and the third pixel area PA3, and may secure different resonance distances depending on the color of light emitted from the light-emitting layer EL. Accordingly, a resonance phenomenon generated between the light traveling from the light-emitting layer EL toward the common electrode CE and the light emitted from the light-emitting layer E and reflected by the reflection electrodes (e.g., the first, second, and third reflection electrodes RE1, RE2, and RE3), so that the light-emitting efficiency and display quality of the display device DD may be improved.

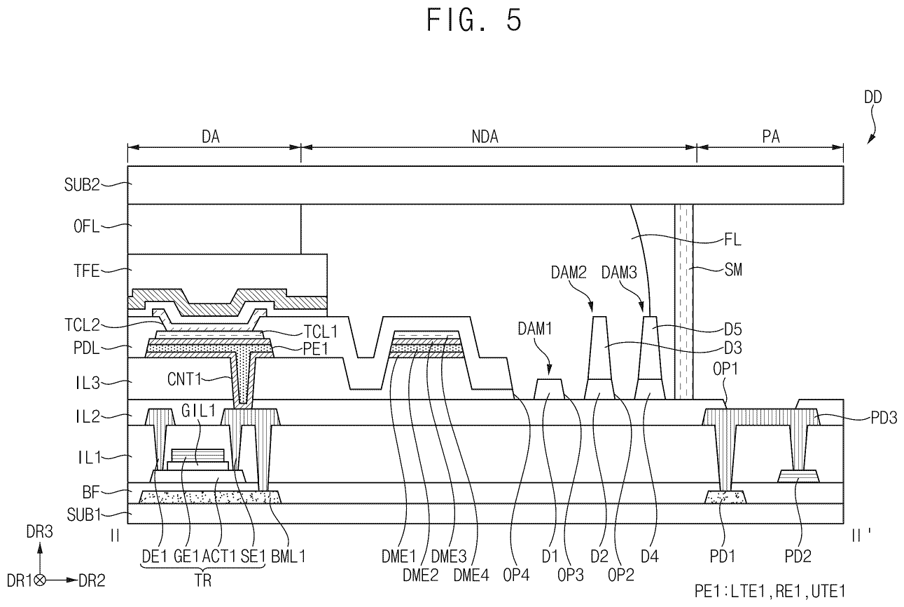

FIG. 5 is a cross-sectional view illustrating an example of a cross-section taken along a line II-II′ of FIG. 1.

Referring to FIGS. 3, 4, and 5, the display device DD may include a first dummy electrode DME1, a second dummy electrode DME2, a third dummy electrode DME3, a fourth dummy electrode DME4, a first dam structure DAM1, a second dam structure DAM2, a third dam structure DAM3, a filling layer FL, a sealing member SM, a first pad electrode PD1, a second pad electrode PD2, and a third pad electrode PD3.

In this specification, the first pad electrode PD1, the second pad electrode PD2, and the third pad electrode PD3 may be referred to as an electrode structure. In addition, the buffer layer BF, the first insulating layer IL1, and the second insulating layer IL2 may be referred to as an insulating structure.

The first dummy electrode DME1, the second dummy electrode DME2, the third dummy electrode DME3, and the fourth dummy electrode DME4 may be disposed in a non-display area NDA. For example, the first dummy electrode DME1, the second dummy electrode DME2, the third dummy electrode DME3, and the fourth dummy electrode DME4 may be adjacent to the display area DA more than the first dam structure DAM1.

In an embodiment, the first dummy electrode DME1, the second dummy electrode DME2, the third dummy electrode DME3, and the fourth dummy electrode DME4 may be sequentially stacked in the third direction DR3 in an order of the first dummy electrode DME1, the second dummy electrode DME2, the third dummy electrode DME3, and the fourth dummy electrode DME4. In an embodiment, in a cross-sectional view, the first dummy electrode DME1, the second dummy electrode DME2, the third dummy electrode DME3, and the fourth dummy electrode DME4 may have a tapered shape in which a width of the first dummy electrode DME1, the second dummy electrode DME2, the third dummy electrode DME3, and the fourth dummy electrode DME4 becomes narrower as the first dummy electrode DME1, the second dummy electrode DME2, the third dummy electrode DME3, and the fourth dummy electrode DME4 are disposed on an upper portion of the third insulating layer IL3. In an embodiment, in the cross-sectional view, the first dummy electrode DME1, the second dummy electrode DME2, the third dummy electrode DME3, and the fourth dummy electrode DME4 may be disposed between the third insulating layer IL3 and the pixel defining layer PDL.

The first dummy electrode DME1 may be disposed on the third insulating layer IL3. In an embodiment, the first dummy electrode DME1 may be disposed in a same layer as the first lower transparent electrode LTE1. For example, the first dummy electrode DME1 may include the same material as the first lower transparent electrode LTE1. For example, the first dummy electrode DME1 may be formed through the same process as the first lower transparent electrode LTE1.

The second dummy electrode DME2 may be disposed on the first dummy electrode DME1. In an embodiment, the second dummy electrode DME2 may be disposed on a same layer as the first reflection electrode RE1. For example, the second dummy electrode DME2 may include a same material as the first reflection electrode RE1. For example, the second dummy electrode DME2 may be formed through a same process as the first reflection electrode RE1.

The third dummy electrode DME3 may be disposed on the first upper transparent electrode UTE1. In an embodiment, the third dummy electrode DME3 may be disposed on a same layer as the first upper transparent electrode UTE1. For example, the third dummy electrode DME3 may include a same material as the first upper transparent electrode UTE1. For example, the third dummy electrode DME3 may be formed through a same process as the first upper transparent electrode UTE1.

The fourth dummy electrode DME4 may be disposed on the first thickness compensation layer TCL1. In an embodiment, the fourth dummy electrode DME4 may be disposed in a same layer as the first thickness compensation layer TCL1. For example, the fourth dummy electrode DME4 may include the same material as the first thickness compensation layer TCL1. For example, the fourth dummy electrode DME4 may be formed through the same process as the first thickness compensation layer TCL1. However, the number of dummy electrodes disposed in the non-display area NDA according to embodiments of the present disclosure may be exemplary and may not be necessarily limited to four.

The first dam structure DAM1 may be disposed on the second insulating layer IL2 of the non-display area NDA. The first dam structure DAM1 may include the first dummy layer D1. In an embodiment, the first dummy layer D1 may be disposed on a same layer as the third insulating layer IL3. For example, the first dummy layer D1 may include a same material as the third insulating layer IL3. For example, the first dummy layer D1 may be formed through the same process as the third insulating layer IL3. However, the number of layers included in the first dam structure DAM1 according to embodiments of the present disclosure may not be necessarily limited thereto, and the first dam structure DAM1 may include two or more layers.

The second dam structure DAM2 may be disposed on the second insulating layer IL2 of the non-display area NDA. The second dam structure DAM2 may be disposed from the first dam structure DAM1 toward the outside of the display device DD. For example, the second dam structure DAM2 may be disposed in the second direction DR2 from the first dam structure DAM1.

The second dam structure DAM2 may include a second dummy layer D2 and a third dummy layer D3. In an embodiment, the second dummy layer D2 may be disposed in a same layer as the third insulating layer IL3. For example, the second dummy layer D2 may include the same material as the third insulating layer IL3. For example, the second dummy layer D2 may be formed through the same process as the third insulating layer IL3.

In an embodiment, the third dummy layer D3 may be disposed on a same layer as the pixel defining layer PDL. For example, the third dummy layer D3 may include a same material as the pixel defining layer PDL. For example, the third dummy layer D3 may be formed through a same process as the pixel defining layer PDL. However, a number of layers included in the second dam structure DAM2 according to embodiments of the present disclosure may not be necessarily limited thereto, and the second dam structure DAM2 may include one or three or more layers.

The third dam structure DAM3 may be disposed on the second insulating layer IL2 of the non-display area NDA. The third dam structure DAM3 may be disposed toward the outside of the display device DD from the second dam structure DAM2. For example, the third dam structure DAM3 may be disposed in the second direction DR2 from the second dam structure DAM2.

The third dam structure DAM3 may include a fourth dummy layer D4 and a fifth dummy layer D5. In an embodiment, the fourth dummy layer D4 may be disposed in a same layer as the third insulating layer IL3. For example, the fourth dummy layer D4 may include a same material as the third insulating layer IL3. For example, the fourth dummy layer (D4) may be formed through a same process as the third insulating layer IL3.

In an embodiment, the fifth dummy layer D5 may be disposed in a same layer as the pixel defining layer PDL. For example, the fifth dummy layer D5 may include the same material as the pixel defining layer PDL. For example, the fifth dummy layer D5 may be formed through the same process as the pixel defining layer PDL. However, a number of layers included in the third dam structure DAM3 according to embodiments of the present disclosure may not be necessarily limited thereto, and the third dam structure DAM3 may include one or three or more layers.

The filling layer FL may be disposed across the display area DA and the non-display area NDA. The filling layer FL may fill an empty space within the display device DD. For example, the filling layer FL may fill the empty space between the first substrate SUB1 and the second substrate SUB2. The filling layer FL may also be disposed in the display area DA, and the filling layer FL may fill the empty space between the thin film encapsulation layer TFE and the optical functional layer OFL within the display area DA.

In an embodiment, the filling layer FL may include a transparent material. For example, the filling layer FL may include a silicone-based resin, an epoxy-based resin, and the like. These may be used alone or in combination with each other. However, materials included in the filling layer FL according to the embodiments of the present disclosure may be exemplary and may not be necessarily limited thereto.

The sealing member SM may be disposed on the second insulating layer IL2 of the non-display area NDA. In an embodiment, the sealing member SM may surround at least a portion of the display area DA in a plan view. The sealing member SM may prevent the filling layer FL from overflowing toward the outside of the display device DD or the organic insulating layers (e.g., the third insulating layer IL3) inside the display panel DP from overflowing toward the outside of the display device DD.

In an embodiment, the sealing member SM may be disposed between the first substrate SUB1 and the second substrate SUB2 in a cross-sectional view. For example, the sealing member SM may bond the first substrate SUB1 and the second substrate SUB2 to each other.

In an embodiment, the sealing member SM may include an organic material. For example, the sealing member SM may include an acrylic resin, a methacrylic resin, a vinyl resin, a polyisoprene, an epoxy resin, a urethane resin, a cellulose resin, and the like. These may be used alone or in combination with each other. For example, the acrylic resin may include butyl acrylate, ethylhexylacrylate, and the like. For example, the methacrylic resin may include propylene glycol methacrylate, tetrahydroperpyrrolidone, and the like. For example, the vinyl resin may include vinyl acetate, N-vinylpyrrolidone, and the like. For example, the epoxy resin may include cycloaliphatic epoxide, and the like. For example, the urethane resin may include urethane acrylate, and the like. The cellulose resin may include cellulose nitrate, and the like. These may be used alone or in combination with each other. However, the present disclosure is not limited thereto, and the sealing member SM may include various materials.

The first pad electrode PD1 may be disposed on the first substrate SUB1 of the pad area PA. In an embodiment, the first pad electrode PD1 may be disposed on the same layer as the first lower metal layer BML1. For example, the first pad electrode PD1 and the first lower metal layer BML1 may include the same material. For example, the first pad electrode (PD1) and the first lower metal layer BML1 may be formed through the same process.

The second pad electrode PD2 may be disposed on the buffer layer BF of the pad area PA. In an embodiment, the second pad electrode PD2 may include the same material as the first gate electrode GE1. In an embodiment, the second pad electrode PD2 may be formed through the same process as the first gate electrode GE1.

The third pad electrode PD3 may be disposed on the first insulating layer IL1 of the pad area PA. In an embodiment, the third pad electrode PD3 may be disposed on the same layer as the first source electrode SE1 and the first drain electrode DE1. In an embodiment, the third pad electrode PD3 may include the same material as the first source electrode SE1 and the first drain electrode DE1. In an embodiment, the third pad electrode PD3 may be formed through a same process as the first source electrode SE1 and the first drain electrode DE1.

A first opening OP1 may be defined in the second insulating layer IL2 to expose one surface (e.g., the upper surface) of the third pad electrode PD3 and penetrate the second insulating layer IL2 in a thickness direction (e.g., the third direction DR3). In an embodiment, the first opening OP1 may extend to the surface of the third pad electrode PD3. In the present specification, the first opening OP1 may be referred to as an opening.

A second opening OP2 may be defined between the second dam structure DAM2 and the third dam structure DAM3 to expose one surface (e.g., an upper surface) of the second insulating layer IL2. A third opening OP3 may be defined between the first dam structure DAM1 and the second dam structure DAM2 to expose one surface (e.g., an upper surface) of the second insulating layer IL2. A fourth opening OP4 may be defined between the first dam structure DAM1 and the third insulating layer IL3 and the pixel defining layer PDL adjacent to the first dam structure DAM1 to expose one surface (e.g., an upper surface) of the second insulating layer IL2.

The first pad electrode PD1, the second pad electrode PD2, and the third pad electrode PD3 may be electrically connected to a power voltage generator, a driving controller, and the like. For example, the display device DD may further include a circuit board disposed on a pad area PA and having one of the power voltage generator and the driving controller mounted, and the first pad electrode PD1, the second pad electrode PD2, and the third pad electrode PD3 may be electrically connected to the circuit board. For example, the first pad electrode PD1, the second pad electrode PD2, and the third pad electrode PD3 may be electrically connected to the circuit board through a conductive tape, a conductive ball, and the like. that fills the first opening OP1.

In the display area DA of FIG. 5, a configuration corresponding to the first pixel area PA1 is illustrated, but the display device DD according to embodiments of the present disclosure may not be necessarily limited thereto.

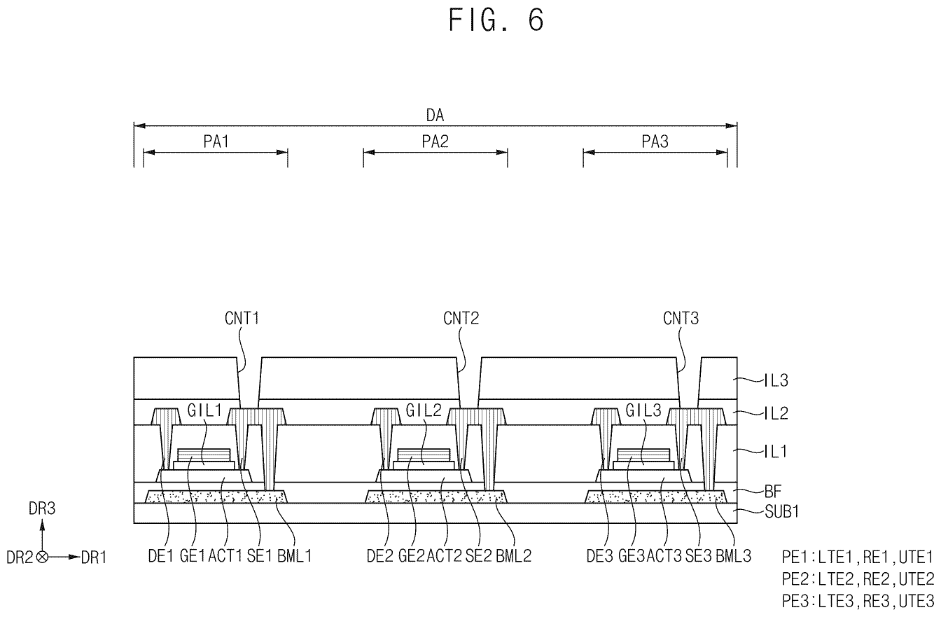

FIGS. 6, 7, 8, 9, 10, 11, 12, 13, 14, 15, 16, 17, and 18 are cross-sectional views explaining for a method of manufacturing the display device of FIG. 3.

Hereinafter, any content that overlaps with the content described with reference to FIGS. 1, 2, 3, 4, and 5 may be omitted or briefly described.

Referring to FIG. 6, the first lower metal layer BML1, the second lower metal layer BML2, and the third lower metal layer BML3 may be formed on the first substrate SUB1. The buffer layer BF may be formed on the first lower metal layer BML1, the second lower metal layer BML2, and the third lower metal layer BNL3. The first active layer ACT1, the second active layer ACT2, and the third active layer ACT3 may be formed on the buffer layer BF.

The first gate insulating layer GIL1 may be formed on the first active layer ACT1. The second gate insulating layer GIL2 may be formed on the second active layer ACT2. The third gate insulating layer GIL3 may be formed on the third active layer ACT3.

The first gate electrode GE1 may be formed on the first gate insulating layer GIL1. The second gate electrode GE2 may be formed on a second gate insulating layer GIL2. The third gate electrode GE3 may be formed on a third gate insulating layer GIL3. In an embodiment, the first gate electrode GE1, the second gate electrode GE2, and the third gate electrode GE3 may be formed through a same process.

The first insulating layer IL1 may be formed on the first gate electrode GE1, the second gate electrode GE2, and the third gate electrode GE3. The first source electrode (SE1), the first drain electrode DE1, the second source electrode SE2, the second drain electrode DE2, the third source electrode SE3, and the third drain electrode DE3 may be formed on the first insulating layer IL1. In an embodiment, the first source electrode SE1, the first drain electrode DE1, the second source electrode SE2, the second drain electrode DE2, the third source electrode SE3, and the third drain electrode DE3 may be formed through a same process.

The second insulating layer IL2 may be formed on the first source electrode SE1, the first drain electrode DE1, the second source electrode SE2, the second drain electrode DE2, the third source electrode SE3, and the third drain electrode DE3. The third insulating layer IL3 may be formed on the second insulating layer IL2.

Specifically, after forming a preliminary second insulating layer that entirely covers the first source electrode SE1, the first drain electrode DE1, the second source electrode SE2, the second drain electrode DE2, the third source electrode SE3, and the third drain electrode DE3, a preliminary third insulating layer that entirely covers the preliminary second insulating layer may be formed on the preliminary second insulating layer. After the third insulating layer is formed, the first contact hole CNT1, the second contact hole CNT2, and the third contact hole CNT3 that simultaneously penetrate the preliminary second insulating layer and the preliminary third insulating layer in a thickness direction (e.g., the third direction DR3) may be formed. Accordingly, a second insulating layer IL2 and a third insulating layer IL3 in which the first contact hole CNT1, the second contact hole CNT2, and the third contact hole CNT3 are formed may be formed.

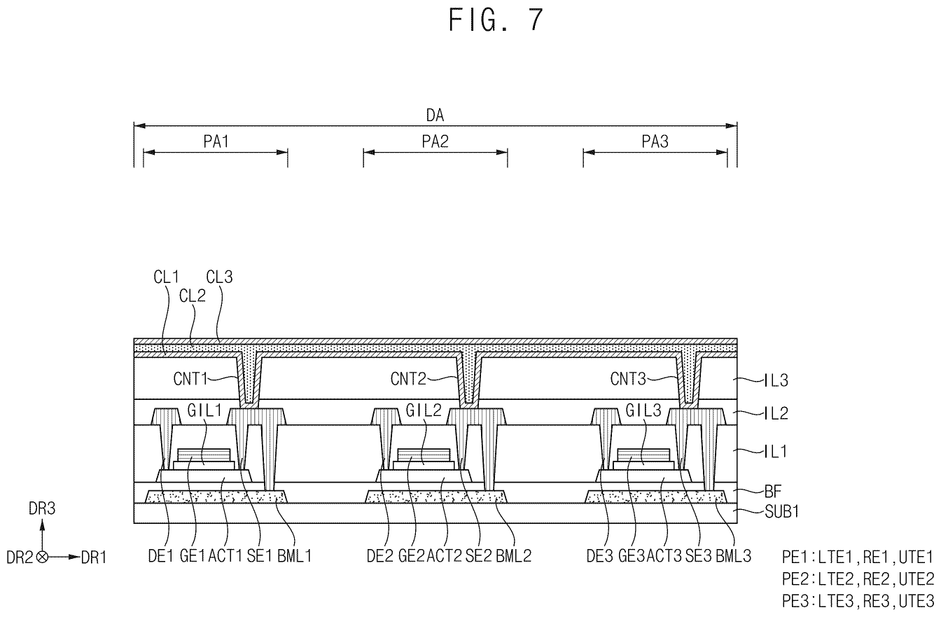

Referring to FIG. 7, a first conductive layer CL1 may be formed on the third insulating layer IL3. For example, the first conductive layer CL1 may be formed over the first pixel area PA1, the second pixel area PA2, and the third pixel area PA3 on the third insulating layer IL3. In an embodiment, the first conductive layer CL1 may fill the first contact hole CNT1, the second contact hole CNT2, and the third contact hole CNT3. In an embodiment, the first conductive layer CL1 may include a transparent material. For example, the transparent material may include indium tin oxide. However, the material included in the first conductive layer CL1 according to embodiments of the present disclosure is not necessarily limited thereto.

A second conductive layer CL2 may be formed on the first conductive layer CL1. For example, the second conductive layer CL2 may be formed over the first pixel area PA1, the second pixel area PA2, and the third pixel area PA3 on the first conductive layer CL1. In an embodiment, the second conductive layer CL2 may include a metal material that reflects light. For example, the second conductive layer CL2 may include silver, titanium, etc. These may be used alone or in combination with each other. However, materials included in the second conductive layer CL2 according to the embodiments of the present disclosure may not be necessarily limited thereto. In an embodiment, the first conductive layer CL1 and the second conductive layer CL2 may include different materials.

A third conductive layer CL3 may be formed over the second conductive layer CL2. For example, the third conductive layer CL3 may be formed over the first pixel area PA1, the second pixel area PA2, and the third pixel area PA3 on the second conductive layer CL2. In an embodiment, the third conductive layer CL3 may include a transparent material. For example, the transparent material may include indium tin oxide. However, materials included in the third conductive layer CL3 according to embodiments of the present disclosure may not be necessarily limited thereto.

In an embodiment, the third conductive layer CL3 may include a different material from the second conductive layer CL2. In an embodiment, the first conductive layer CL1 and the third conductive layer CL3 may include the same material. However, the first conductive layer CL1 and the third conductive layer CL3 according to embodiments of the present disclosure are not necessarily limited thereto, and the first conductive layer CL1 and the third conductive layer CL3 may include different transparent materials.

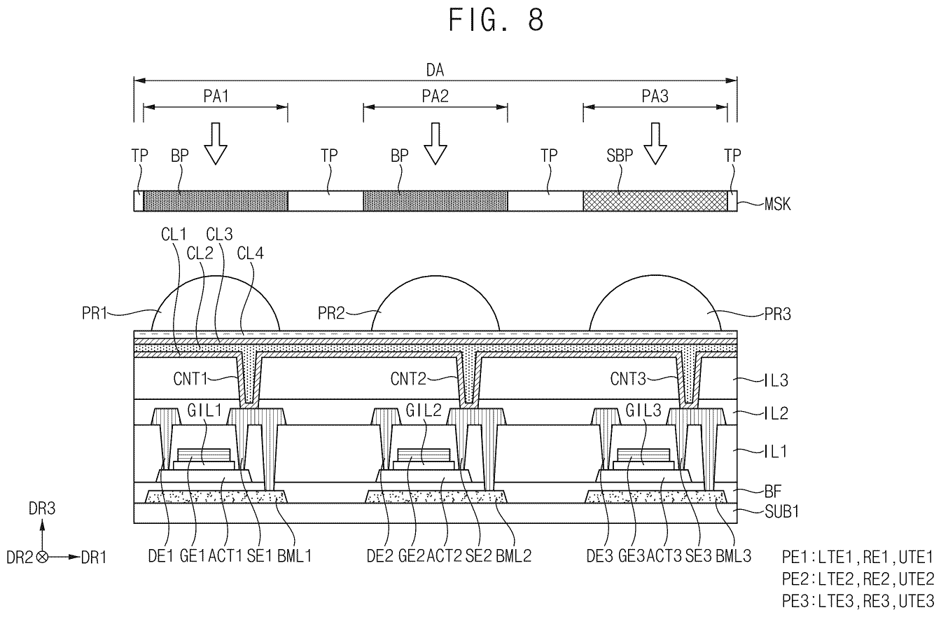

Referring to FIG. 8, a fourth conductive layer CL4 may be formed on the third conductive layer CL3. For example, the fourth conductive layer CL4 may be formed over the first pixel area PA1, the second pixel area PA2, and the third pixel area PA3 on the third conductive layer CL3. In an embodiment, the fourth conductive layer CL4 may include a transparent material. For example, the transparent material may include indium zinc oxide. However, the material included in the fourth conductive layer CL4 according to embodiments of the present disclosure may not be not necessarily limited thereto. In an embodiment, the fourth conductive layer CL4 may include a material different from each of the first conductive layer CL1, the second conductive layer CL2, and the third conductive layer CL3.

In the disclosure, the third conductive layer CL3 may be referred to as the second conductive layer, and the fourth conductive layer CL4 may be referred to as the third conductive layer.

In an embodiment, the weight ratio (wt %) of indium (In) and zinc (Zn) included in the fourth conductive layer CL4 may be about 6:4 to about 8:2. Preferably, the weight ratio of indium (In) and zinc (Zn) included in the fourth conductive layer CL4 may be about 6.5:3.5 to about 7.5:2.5. More preferably, the weight ratio of indium (In) and zinc (Zn) included in the fourth conductive layer CL4 may be about 7:3.

The first photoresist PR1, the second photoresist PR2, and the third photoresist PR3 may be formed on the fourth conductive layer CL4. The first photoresist PR1 may be disposed in the first pixel area PA1 on the fourth conductive layer CL4. The second photoresist PR2 may be disposed in the second pixel area PA2 on the fourth conductive layer CL4. The third photoresist PR3 may be disposed in the third pixel area PA3 on the fourth conductive layer CL4.

In an embodiment, the first photoresist PR1, the second photoresist PR2, and the third photoresist PR3 may have a same thickness.

In an embodiment, the first photoresist PR1, the second photoresist PR2, and the third photoresist PR3 may include the same material. For example, the first photoresist PR1, the second photoresist PR2, and the third photoresist PR3 may be a positive photoresist or a negative photoresist.

In an embodiment, a first exposure process may be performed on the first photoresist PR1, the second photoresist PR2, and the third photoresist PR3. For example, the first exposure process may be performed on the first photoresist PR1, the second photoresist PR2, and the third photoresist PR3 using a mask MSK including a blocking portion BP, a transmitting portion TP, and a semi-transmitting portion SBP. The blocking portion BP is a portion of the mask MSK that does not transmit light, the transmitting portion TP of the mask MSK is another portion of the mask MSK that transmits light, and the semi-transmitting portion SBP may be still another portion of the mask MSK that has a greater light transmittance than the blocking portion BP and a lower light transmittance than the transmitting portion TP.

In an embodiment, the blocking portion BP of the mask MSK may be disposed corresponding to the first photoresist PR1 and the second photoresist PR2. In an embodiment, the semi-transparent portion SBP of the mask MSK may be disposed to correspond to the third photoresist PR3. In an embodiment, the transmitting portion TP of the mask MSK may be disposed not to correspond to the first photoresist PR1, the second photoresist PR2, and the third photoresist PR3.

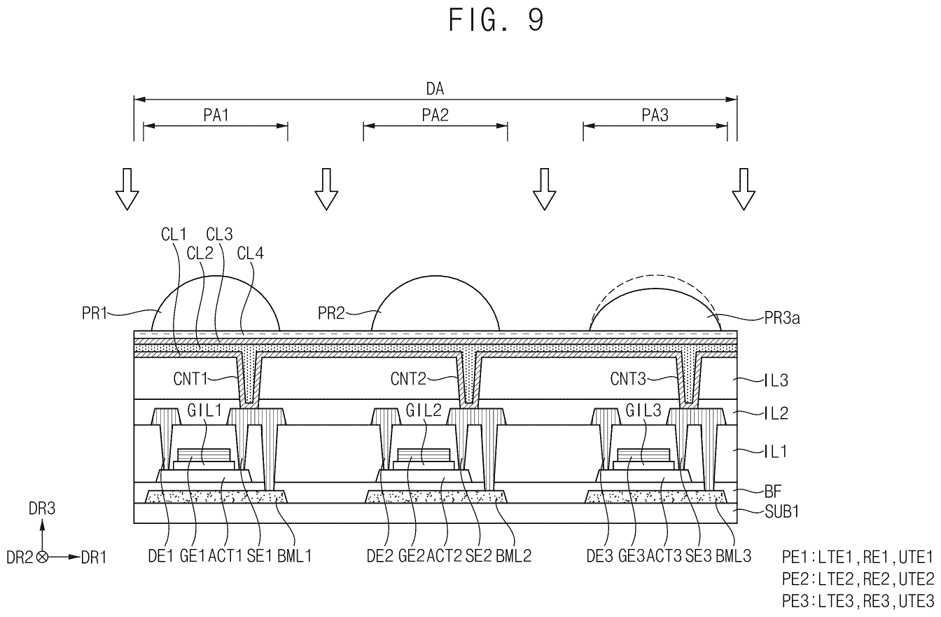

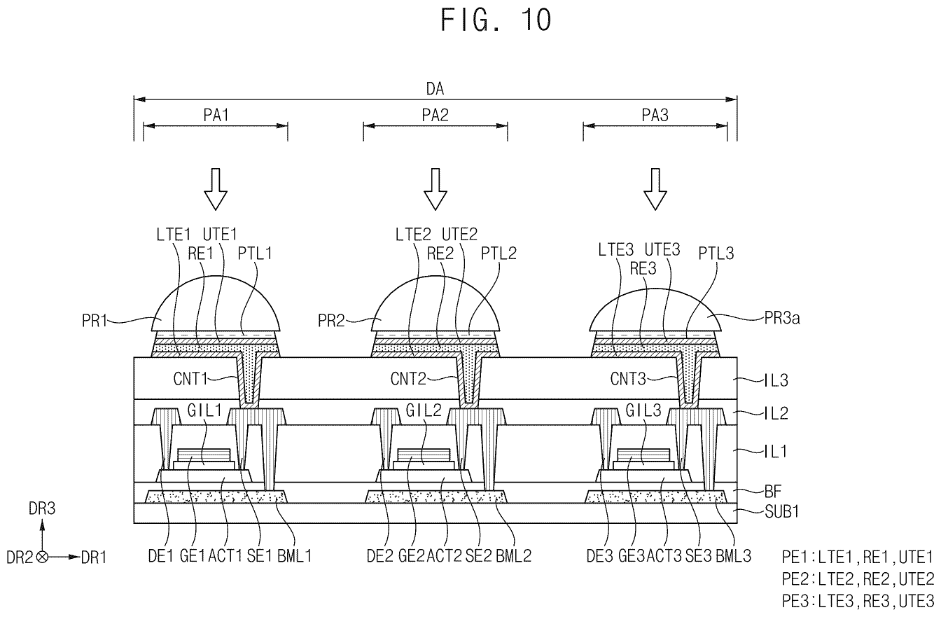

Referring to FIGS. 9 and 10, after the first exposure process is performed, a portion of the third photoresist PR3 may be removed. Accordingly, a third photoresist PR3a having a thickness less than a thickness of each of the first photoresist PR1 and the second photoresist PR2 may be formed.

After the first exposure process is performed, a portion of each of the first, second, third and fourth conductive layers CL1, CL2, CL3, and CL4 that are spaced apart from or do not overlap in a plan view with the first photoresist PR1, the second photoresist PR2, and the third photoresist PR3a may be removed. In an embodiment, a portion of each of the first second, third and fourth conductive layers CL1, CL2, CL3, and CL4 may be removed through a first etching process. Through the first etching process, a first pixel electrode PE1 and a first preliminary thickness compensation layer PTL1 may be formed in the first pixel area PA1. Through the first etching process, a second pixel electrode PE2 and a second preliminary thickness compensation layer PTL2 may be formed in the second pixel area PA2. Through the first etching process, a third pixel electrode PE3 and a third preliminary thickness compensation layer PTL3 may be formed in the third pixel area PA3.

Specifically, a portion of the first conductive layer CL1 may be removed to form a first lower transparent electrode LTE1, a second lower transparent electrode LTE2, and a third lower transparent electrode LTE3. A portion of the second conductive layer CL2 may be removed to form a first reflection electrode RE1, a second reflection electrode RE2, and a third reflection electrode RE3. A portion of the third conductive layer CL3 may be removed to form a first upper transparent electrode UTE1, a second upper transparent electrode UTE2, and a third upper transparent electrode UTE3. A portion of the fourth conductive layer CL4 may be removed to form the first preliminary thickness compensation layer PTL1, the second preliminary thickness compensation layer PTL2, and the third preliminary thickness compensation layer PTL3.

In an embodiment, the first lower transparent electrode LTE1, the first reflection electrode RE1, the first upper transparent electrode UTE1, and the first preliminary thickness compensation layer PTL1 may overlap the first pixel area PA1 in a plan view. In an embodiment, the second lower transparent electrode LTE2, the second reflection electrode RE2, the second upper transparent electrode UTE2, and the second preliminary thickness compensation layer PTL2 may overlap the second pixel area PA2 in a plan view. In an embodiment, the third lower transparent electrode LTE3, the third reflection electrode RE3, the third upper transparent electrode UTE3, and the third preliminary thickness compensation layer PTL3 may overlap the third pixel area PA3 in a plan view. In other words, only a portion overlapping the first pixel area PA1, the second pixel area PA2, and the third pixel area PA3 of each of the first, second, third, and fourth conductive layers CL1, CL2, CL3, and CL4 may not be removed through the first etching process.

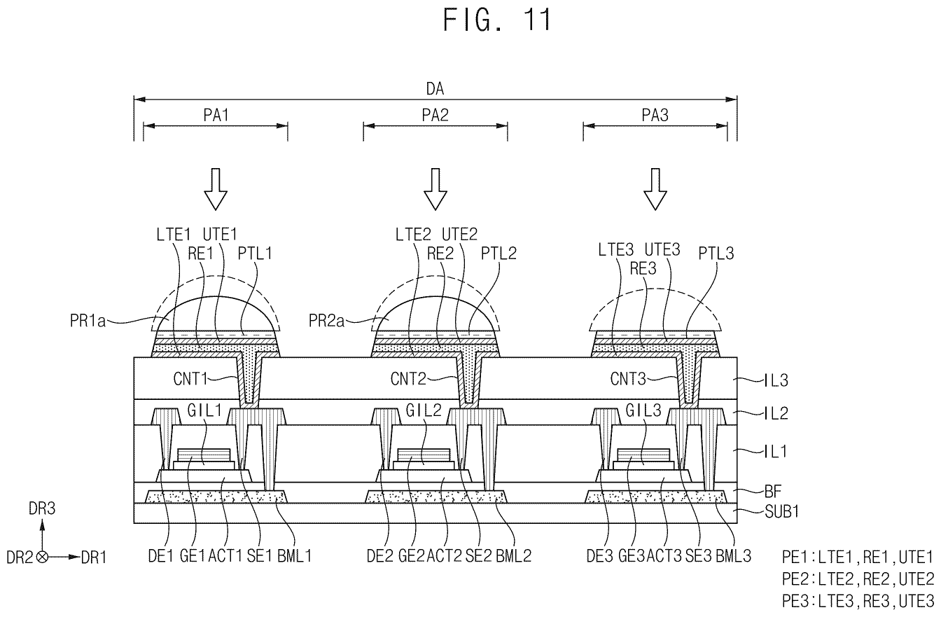

Referring to FIGS. 10 and 11, a portion of each of the first photoresist PR1 and the second photoresist PR2 may be removed. Accordingly, a thickness of each of the first photoresist PR1 and the second photoresist PR2 may be reduced. The third photoresist PR3a formed on the third preliminary thickness compensation layer PTL3 may be removed. For example, while a portion of each of the first photoresist PR1 and the second photoresist PR2 is removed, the third photoresist PR3a may be entirely removed.

Specifically, a first ashing process may be performed on the first photoresist PR1, the second photoresist PR2, and the third photoresist PR3a. Accordingly, each of the first photoresist PR1 and the second photoresist PR2 may be removed by an amount equal to the amount by which the third photoresist PR3a is removed. The first photoresist PR1a on which the first ashing process is performed may remain on the first preliminary thickness compensation layer PTL1. In addition, the second photoresist PR2a on which the first ashing process is performed may remain on the second preliminary thickness compensation layer PTL2.

In an embodiment, the first photoresist PR1a on which the first ashing process is performed may entirely cover the upper surface of the first preliminary thickness compensation layer PTL1. In an embodiment, the second photoresist PR2a on which the first ashing process is performed may entirely cover the upper surface of the second preliminary thickness compensation layer PTL2.

Referring to FIGS. 8, 11, and 12, the third preliminary thickness compensation layer PTL3 may be removed in the third pixel area PA3. For example, the third preliminary thickness compensation layer PTL3 formed on the third upper transparent electrode UTE3 may be entirely removed through the second etching process. In addition, while the third preliminary thickness compensation layer PTL3 is entirely removed, a portion of each of the first preliminary thickness compensation layer PTL1 and the second preliminary thickness compensation layer PTL2 may be removed.

In an embodiment, the etchant used in the second etching process may have a relatively large etching selectivity with respect to the third preliminary thickness compensation layer PTL3. For example, an etching selectivity of the etchant used in the second etching process with respect to the third preliminary thickness compensation layer PTL3 may be greater than an etching selectivity of the etchant with respect to the third upper transparent electrode UTE3.

Specifically, an etching selectivity of the etchant with respect to indium zinc oxide may be greater than an etching selectivity of the etchant with respect to indium tin oxide. Accordingly, the third preliminary thickness compensation layer TCL3 may be selectively etched through the first etching process. In other words, the etching selectivity of the etchant with respect to the fourth conductive layer CL4 may be greater than the etching selectivity of the etchant with respect to the third conductive layer CL3.

In an embodiment, an etching selectivity of the etchant with respect to the first photoresist PR1a may be less than an etching selectivity of the etchant with respect to the first preliminary thickness compensation layer PTL1. Since the first photoresist PR1a covers the upper portion of the first preliminary thickness compensation layer PTL1, the side portion of the first preliminary thickness compensation layer PTL1 may be partially removed through the etchant. Accordingly, a portion of the first preliminary thickness compensation layer PTL1 may be removed to form the first thickness compensation layer TCL1.

In an embodiment, the etching selectivity of the etchant with respect to the second photoresist PR2a may be less than the etching selectivity of the etchant with respect to the second preliminary thickness compensation layer PTL2. Since the first photoresist PR1a covers the upper portion of the first preliminary thickness compensation layer PTL1, the side of the second preliminary thickness compensation layer PTL2 may be partially removed through the etchant. Accordingly, a portion of the second preliminary thickness compensation layer PTL2 before the second etching process is performed may be removed, thereby forming the second preliminary thickness compensation layer PTL2a on which the first etching process is performed.

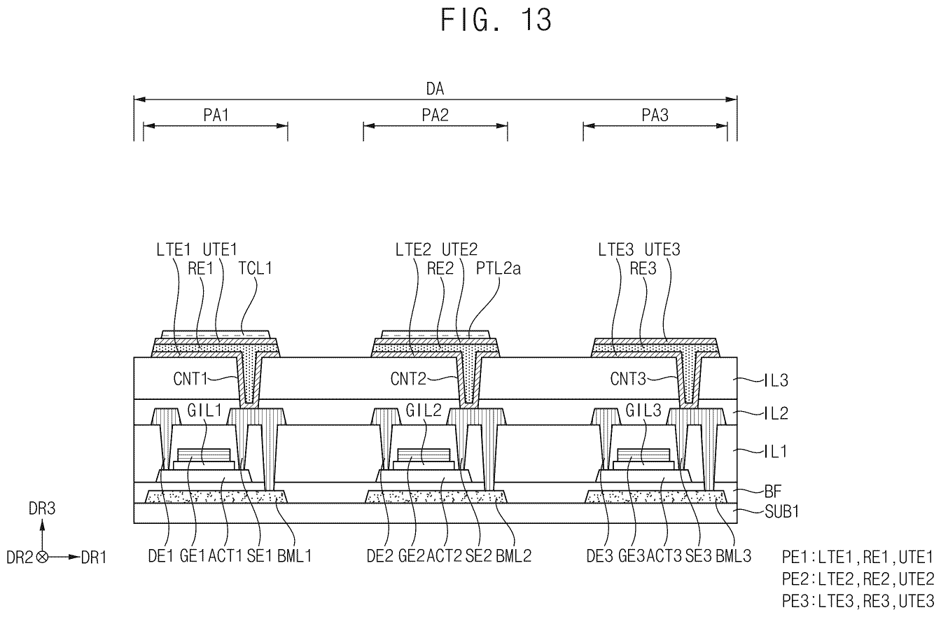

Referring to FIG. 13, after the second etching process is performed and the third preliminary thickness compensation layer TCL3 is entirely removed, the first photoresist PR1a and the second photoresist PR2a may be removed. For example, through the second ashing process, the first photoresist PR1a may be entirely removed from the first thickness compensation layer TCL1. In addition, through the second ashing process, the second photoresist PR2a may be entirely removed from the second preliminary thickness compensation layer PTL2a.

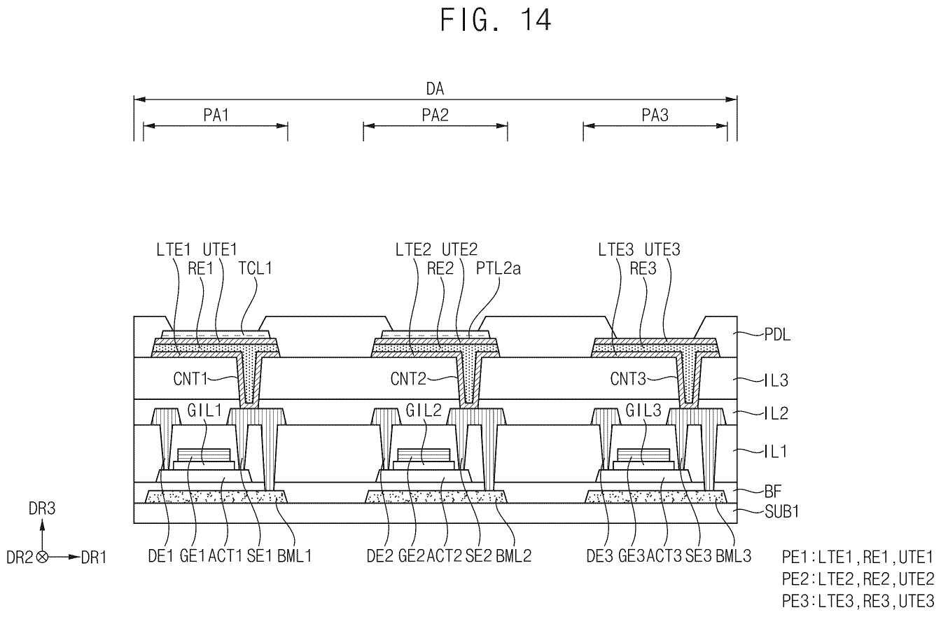

Referring to FIG. 14, a pixel defining layer PDL may be formed on the third insulating layer IL3. The pixel defining layer PDL may be formed between adjacent pixel areas. For example, the pixel defining layer PDL may be formed between the first pixel area PA1 and the second pixel area PA2 that are adjacent to each other. For example, the pixel defining layer PDL may be formed between the second pixel area PA2 and the third pixel area PA3 that are adjacent to each other. For example, the pixel defining layer PDL may be formed between the first pixel area PA1 and the third pixel area PA3 that are adjacent to each other.

In an embodiment, the pixel defining layer PDL may be formed to partially overlap each of the pixel areas. For example, one pixel defining layer PDL may partially overlap each of the first pixel area PA1 and the second pixel area PA2 in a plan view. For example, one pixel defining layer PDL may partially overlap each of the second pixel area PA2 and the third pixel area PA3 in a plan view. For example, one pixel defining layer PDL may partially overlap each of the first pixel area PA1 and the third pixel area PA3 in a plan view.

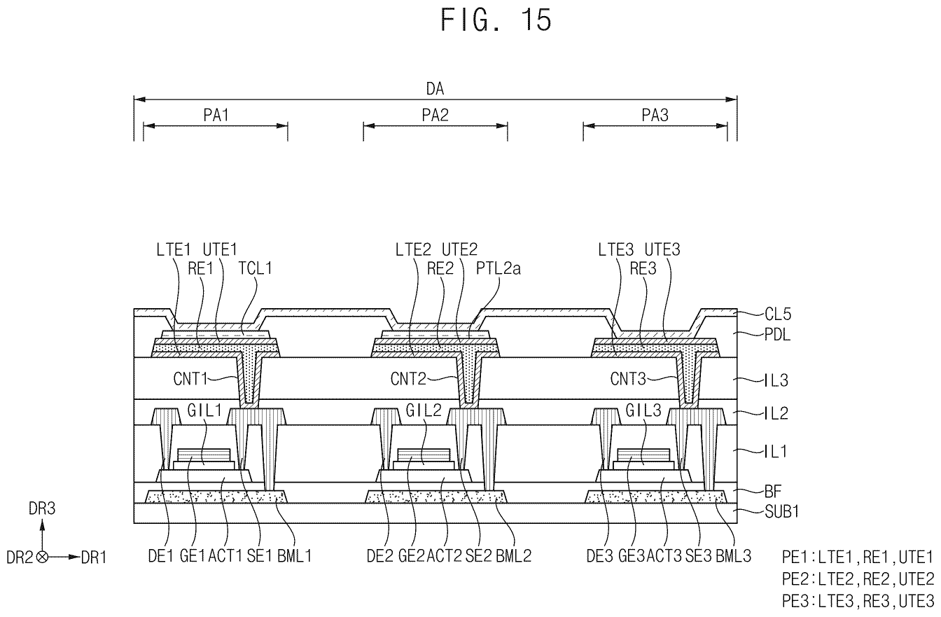

Referring to FIG. 7 and FIG. 15, a fifth conductive layer CL5 may be formed on a pixel defining layer PDL. In an embodiment, the fifth conductive layer CL5 may include a different material from the fourth conductive layer CL4. In an embodiment, the fifth conductive layer CL5 may include the same material as the first conductive layer CL1 and the third conductive layer CL3. In an embodiment, the fifth conductive layer CL5 may include a transparent material. For example, the transparent material may include indium tin oxide. However, the material included in the fifth conductive layer CL5 according to embodiments of the present disclosure may not be necessarily limited thereto.

In the disclosure, the fifth conductive layer CL5 may be referred to as a first conductive layer.

The fifth conductive layer CL5 may be formed over the entire display area DA. For example, the fifth conductive layer CL5 may be formed over the first pixel area PA1, the second pixel area PA2, and the third pixel area PA3. Specifically, the fifth conductive layer CL5 may be deposited over the first thickness compensation layer TCL1, the second preliminary thickness compensation layer PTL2a, the third upper transparent electrode UTE3, and the pixel defining layer PDL.

In an embodiment, the fifth conductive layer CL5 may be formed over an upper surface and a side surface of the pixel defining layer PDL. In an embodiment, the fifth conductive layer CL5 may fill the first hole of the pixel defining layer PDL that exposes one surface (e.g., the upper surface) of the first thickness compensation layer TCL1. In an embodiment, the fifth conductive layer CL5 may fill the second hole of the pixel defining layer PDL that exposes one surface (e.g., the upper surface) of the second preliminary thickness compensation layer PTL2a. In an embodiment, the fifth conductive layer CL5 may fill the third hole of the pixel defining layer PDL exposing a side (e.g., the upper side) of the third upper transparent electrode UTE3.

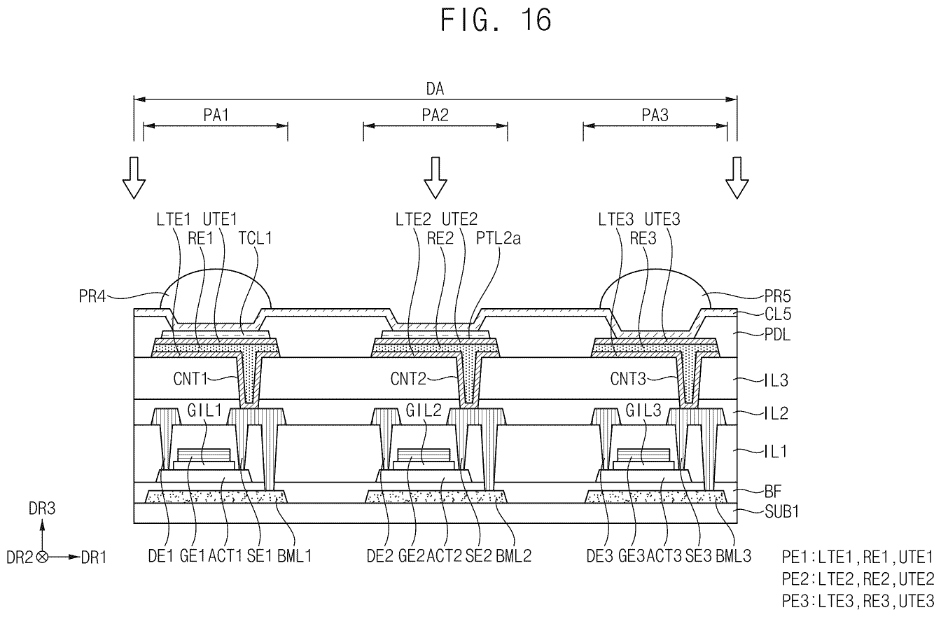

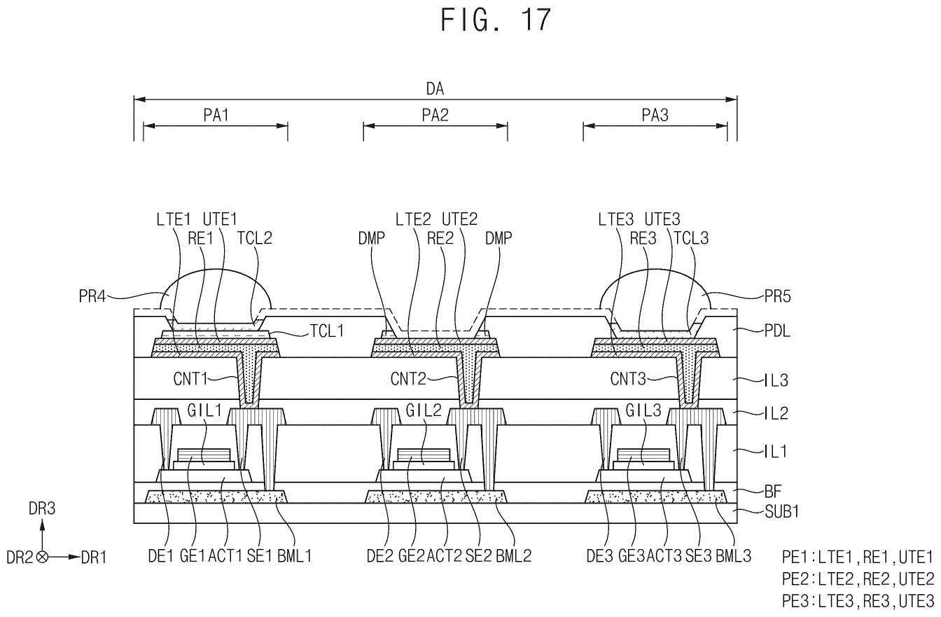

Referring to FIGS. 16 and 17, a fourth photoresist PR4 may be formed on a portion of the fifth conductive layer CL5 located in the first pixel area PA1. In addition, a fifth photoresist PR5 may be formed on a portion of the fifth conductive layer CL5 located in the third pixel area PA3.

In an embodiment, the fourth photoresist PR4 and the fifth photoresist PR5 may include the same material. For example, the fourth photoresist PR4 and the fifth photoresist PR5 may be a positive photoresist or a negative photoresist.

In an embodiment, the fourth photoresist PR4 may overlap the first thickness compensation layer TCL1 in a plan view. In an embodiment, the fifth photoresist PR5 may overlap the third upper transparent electrode UTE3 in a plan view. In an embodiment, the photoresist may not be disposed in the second pixel area PA2.

A second exposure process may be performed on the fifth conductive layer CL5 on which the fourth photoresist PR4 and the fifth photoresist PR5 are formed on the upper side. After the second exposure process is performed, a portion of the fifth conductive layer CL5 may be removed. For example, after the second exposure process is performed, a third etching process may be performed on the fifth conductive layer CL5. Through the third etching process, a portion of the fifth conductive layer CL5 that does not overlap with each of the fourth photoresist PR4 and the fifth photoresist PR5 in a plan view may be removed. Accordingly, a portion of the fifth conductive layer CL5 may be removed to form a second thickness compensation layer TCL2 in the first pixel area PA1. In addition, a portion of the fifth conductive layer CL5 may be removed to form a third thickness compensation layer TCL3 in the third pixel area PA3.

Specifically, in the first pixel area PA1, a portion of the fifth conductive layer CL5 formed on the side surface of the pixel defining layer PDL may remain, so that an edge portion of the second thickness compensation layer TCL2 may extend along the side surface of the pixel defining layer PDL. In addition, in the third pixel area PA3, a portion of the fifth conductive layer CL5 formed on the side surface of the pixel defining layer PDL may remain, so that an edge portion of the third thickness compensation layer TCL3 may extend along the side surface of the pixel defining layer PDL.

After the fifth conductive layer CL5 is removed, a portion of the second preliminary thickness compensation layer PTL2a disposed in the second pixel area PA2 may be removed. Specifically, a central portion of the second preliminary thickness compensation layer PTL2a disposed within the second hole of the pixel defining layer PDL may be removed. An edge portion of the second preliminary thickness compensation layer PTL2a covered by the pixel defining layer PDL may remain. Accordingly, the edge portion of the second preliminary thickness compensation layer PTL2a may remain and be formed as a dummy pattern DMP.

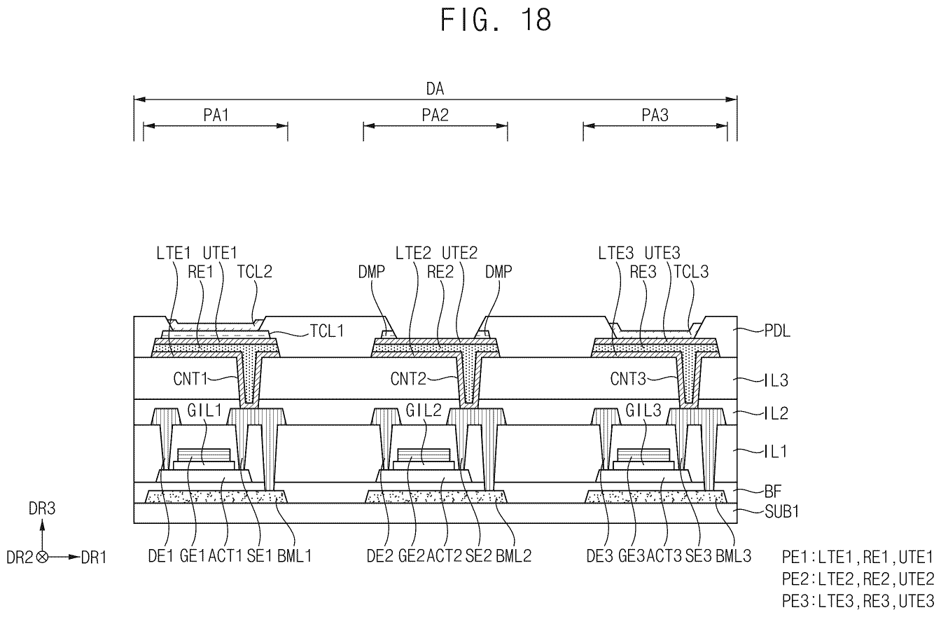

Referring to FIG. 18, after the third etching process is performed to form the second thickness compensation layer TCL2 and the third thickness compensation layer TCL3, respectively, the fourth photoresist PR4 and the fifth photoresist PR5 may be removed. For example, the fourth photoresist PR4 may be entirely removed from the second thickness compensation layer TCL2 through the third ashing process. In addition, the fifth photoresist PR5 may be entirely removed from the third thickness compensation layer TCL3 through the third ashing process.

Referring further to FIG. 3, after the fourth photoresist PR4 and the fifth photoresist PR5 are removed, the light-emitting layer EL, the common electrode CE, the thin film encapsulation layer TFE, the optical functional layer OFL, and the second substrate SUB2 are formed, so that the display device DD of FIG. 1 may be manufactured.

As described above, in the manufacturing method of the display device DD according to the embodiments of the present disclosure, a portion of the fourth conductive layer CL4 disposed in the third pixel area PA3 may be removed using an etchant, a portion of the fifth conductive layer CL5 disposed in the second pixel area PA2 and the third pixel area PA3 may be removed, and the second preliminary thickness compensation layer PTL2a formed from the fourth conductive layer CL4 disposed in the second pixel area PA2 may be removed. Accordingly, the first thickness compensation layer TCL1 and the second thickness compensation layer TCL2 may be formed in the first pixel area PA1, and the third thickness compensation layer TCL3 may be formed in the third pixel area PA3. Accordingly, a target resonance distance may be secured without directly etching the upper transparent electrodes (e.g., the first, second, and third transparent electrodes UTE1, UTE2, and UTE3). Accordingly, a display device DD with improved durability may be easily manufactured.

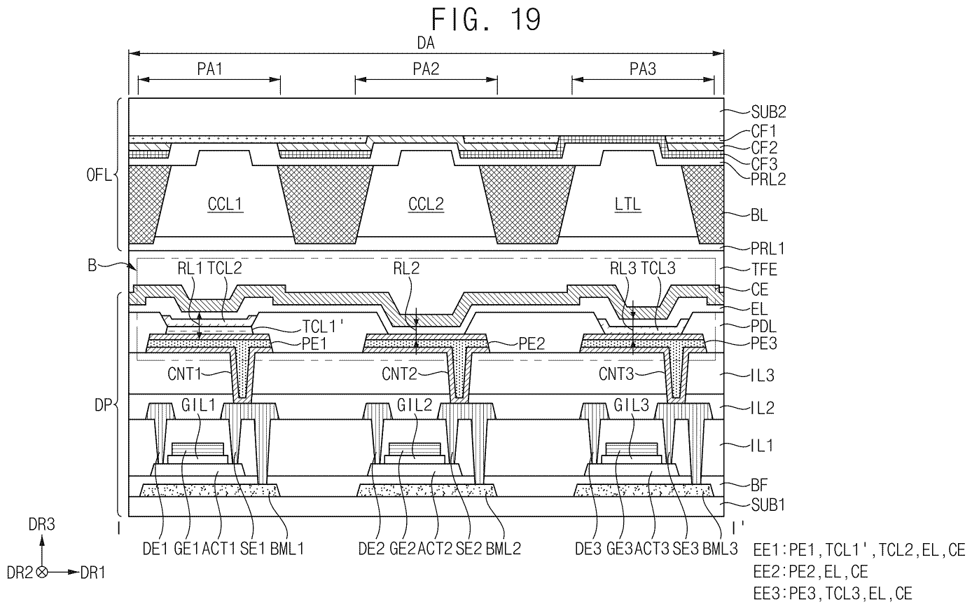

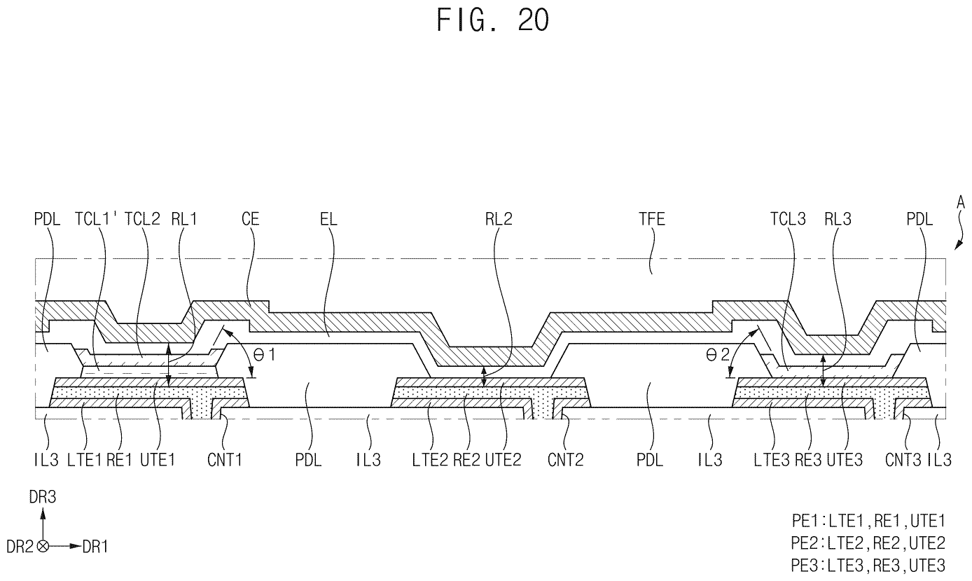

FIG. 19 is a cross-sectional view illustrating another example of a cross-section taken along a line I-I′ of FIG. 1. FIG. 20 is an enlarged cross-sectional view illustrating an area B of FIG. 19.

A structure of the display device DD described with reference to FIGS. 19 and 20 may be substantially a same as or similar to the structure of the display device DD described with reference to FIGS. 3 and 4 except that a size of the first thickness compensation layer TCL1′ and the dummy pattern DMP are not disposed.

Hereinafter, overlapping contents with the structure of the display device DD described with reference to FIGS. 3 and 4 may be omitted or briefly described.

Referring to FIGS. 19 and 20, the display panel DP may include the first thickness compensation layer TCL1'. In an embodiment, a size of the first thickness compensation layer TCL1′ may be less than a size of the first thickness compensation layer TCL1 of FIG. 4. Specifically, a length of the first thickness compensation layer TCL1′ in the first direction DR1 may be less than a length of the first thickness compensation layer TCL1 in the first direction DR1 of FIG. 4.

In addition, the length of the first thickness compensation layer TCL1′ in the second direction DR2 may be less than the length of the first thickness compensation layer TCL1 in the second direction DR2 of FIG. 4. In an embodiment, the dummy pattern DMP of FIG. 3 may not be disposed around the second upper transparent electrode UTE2 disposed in the second pixel area PA2. Specifically, in a cross-section view, no components other than the second upper transparent electrode UTE2 and the pixel definition layer PDL may be disposed between the pixel definition layer PDL and the second upper transparent electrode UTE2.

As described above, in the display device DD according to the embodiments of the present disclosure, a first reflection electrode RE1, a transparent electrode (e.g., a first upper transparent electrode UTE1) sequentially disposed on the first reflection electrode RE1, the first thickness compensation layer TCL1′ and a second thickness compensation layer TCL2 may be disposed in the first pixel area PA1. In addition, a third reflection electrode RE3, the transparent electrode (e.g., the third upper transparent electrode UTE3) sequentially disposed on the third reflection electrode RE3 and the third thickness compensation layer TCL3 may be disposed in the third pixel area PA3. Accordingly, the common electrode CE disposed on the first pixel electrode PE1, the second pixel electrode PE2, and the third pixel electrode PE3 has different heights in each of the first pixel area PA1, the second pixel area PA2, and the third pixel area PA3, and may secure different resonance distances depending on the color of the light emitted from the light-emitting layer EL. Accordingly, a resonance phenomenon occurs between the light traveling from the light-emitting layer EL toward the common electrode CE and the light emitted from the light-emitting layer EL and reflected by the reflection electrodes (e.g., the first, second, and third reflection electrodes RE1, RE2, and RE3), so that the light-emitting efficiency and display quality of the display device DD may be improved.

In addition, a dummy pattern covered by the pixel-defining layer PDL may not be disposed around the second upper transparent electrode UTE2 disposed in the second pixel area PA2. Accordingly, since the phenomenon of the common electrode CE being short-circuited due to the dummy pattern may be prevented, the luminous efficiency and display quality of the display device DD may be further improved. In addition, since defects occurring within the display device DD are reduced, the durability of the display device DD may be improved.

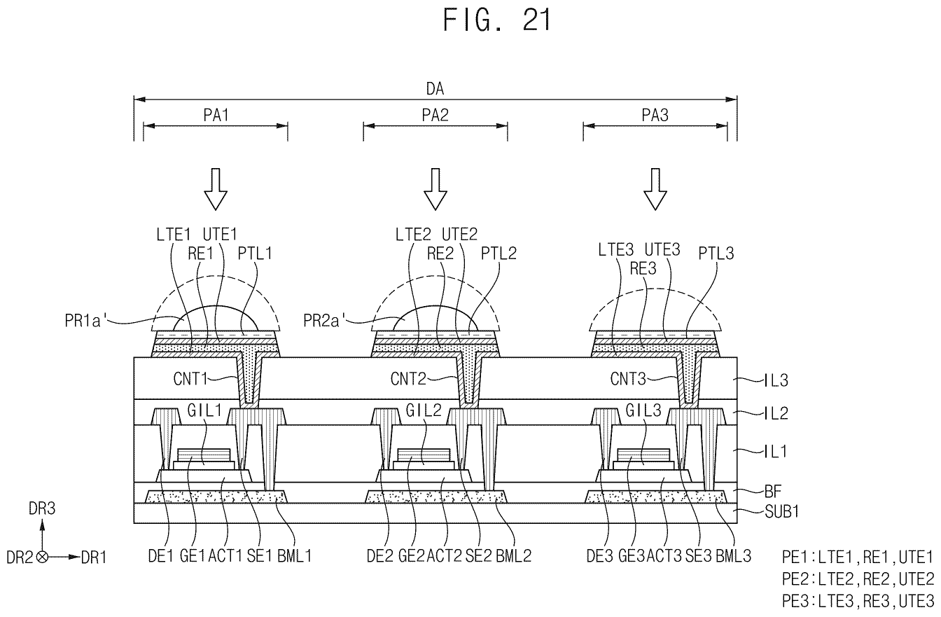

FIGS. 21, 22, 23, and 24 are cross-sectional views explaining for a method of manufacturing the display device of FIG. 20.

A method for manufacturing the display device DD described with reference to FIGS. 21, 22, 23, and 24 may be substantially a same or similar to the method for manufacturing the display device DD described with reference to FIGS. 6, 7, 8, 9 ,10, 11, 12, 13, 14, 15, 16, 17, and 18, except for a process of manufacturing the first thickness compensation layer TCL1′.

Hereinafter, any content overlapping with the content described with reference to FIGS. 6, 7, 8, 9 ,10, 11, 12, 13, 14, 15, 16, 17, 18, 19, and 20 may be omitted or briefly described.

Referring to FIGS. 10 and 21, a portion of each of the first photoresist PR1 and the second photoresist PR2 may be removed through the first ashing process. The third photoresist PR3 may be entirely removed on the third preliminary thickness compensation layer PTL3 through the first ashing process.

In an embodiment, the first photoresist PR1a′ on which the first ashing process has been performed may partially cover the upper surface of the first preliminary thickness compensation layer PTL1 in a plan view. In an embodiment, the second photoresist PR2a′ on which the first ashing process is performed may partially cover the upper surface of the second preliminary thickness compensation layer PTL2 in a plan view.

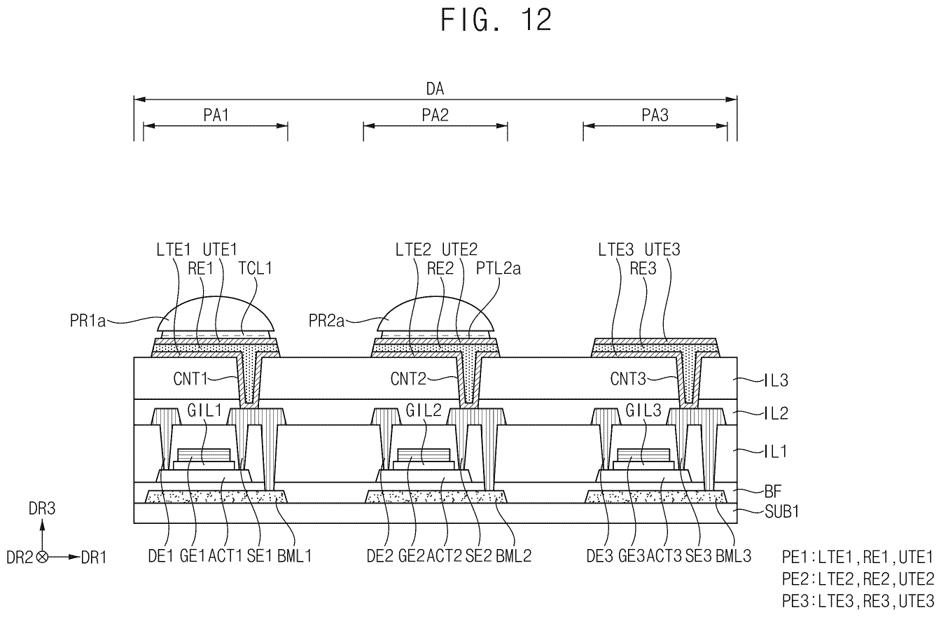

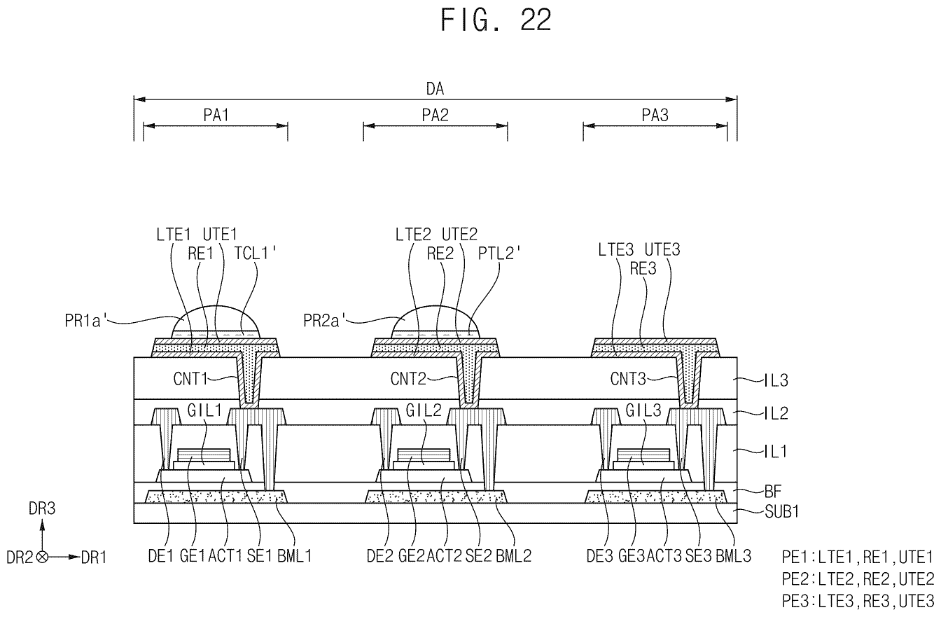

Referring to FIGS. 21 and 22, the third preliminary thickness compensation layer PTL3 in the third pixel area PA3 may be entirely removed through a second etching process. The first thickness compensation layer TCL1 and the second preliminary thickness compensation layer PTL2a′ may be formed through the second etching process. In a plan view, the size of the first thickness compensation layer TCL1 may be less than the first thickness compensation layer TCL1 of FIG. 12. In a plan view, a size of the second preliminary thickness compensation layer PTL2a′ may be less than the second thickness compensation layer PTL2 of FIG. 12.

In other words, an amount of the etchant used in the second etching process of FIG. 22 may be greater than an amount of the etchant used in the second etching process of FIG. 12. Specifically, depending on the etchant used in the second etching process of FIG. 22, the dummy pattern DMP of FIG. 3 may not be formed by the second preliminary thickness compensation layer PTL2a′.

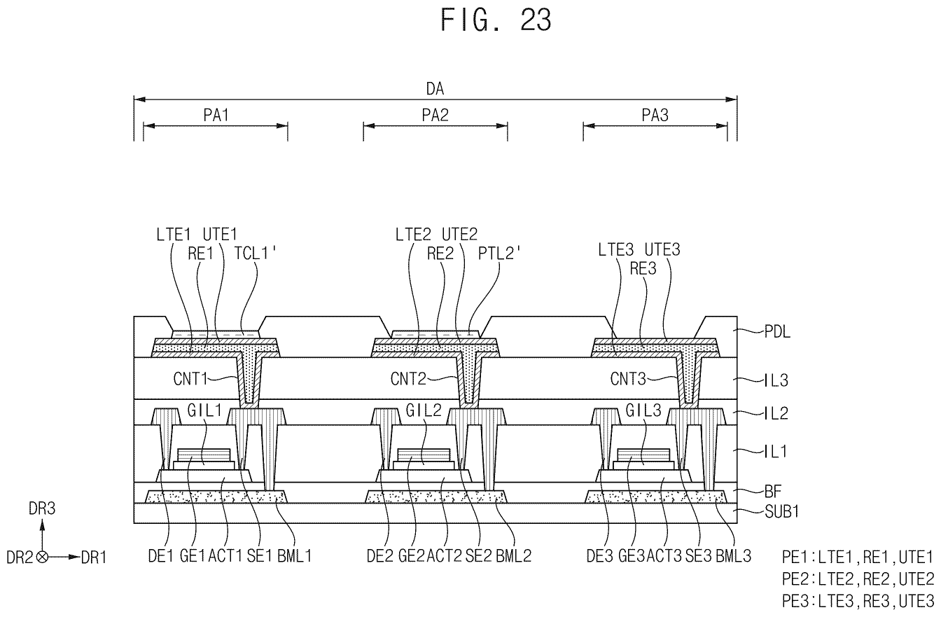

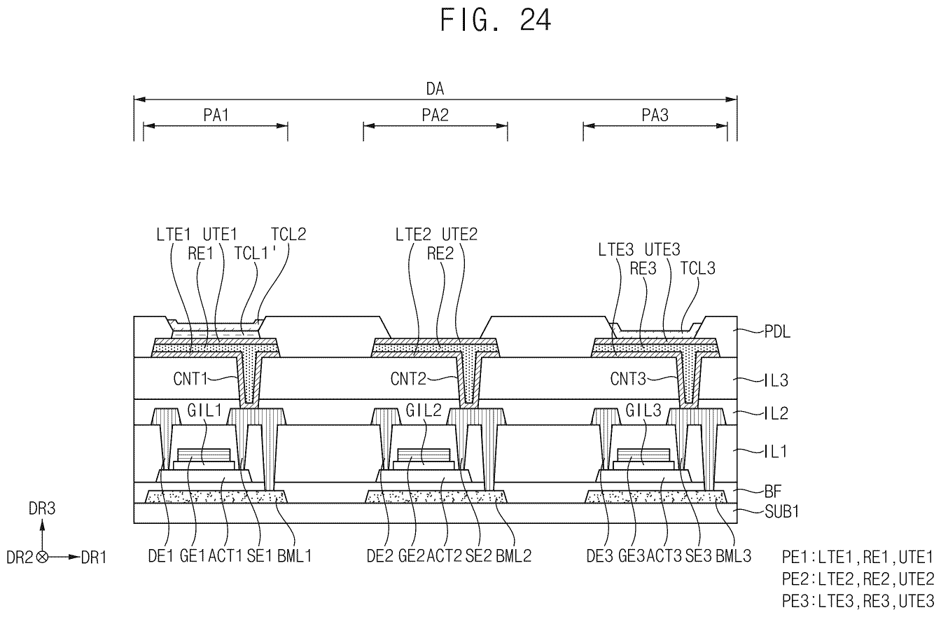

Referring to FIGS. 23 and 24, after the first photoresist PR1a′ and the second photoresist PR2a′ are removed, a pixel defining layer PDL may be formed on the third insulating layer IL3. In the second pixel area PA2, the second preliminary thickness compensation layer PTL2a′ may be disposed within the second hole of the pixel defining layer PDL. Specifically, the edge of the second preliminary thickness compensation layer PTL2a′ is not covered by the pixel defining layer PDL, and the edge of the second preliminary thickness compensation layer PTL2a′ may be exposed by the second hole.

In FIG. 23, the edge of the first thickness compensation layer TCL1 is illustrated as being covered by the pixel defining layer PDL, however the first thickness compensation layer TCL1 according to embodiments of the present disclosure may not be necessarily limited thereto. For example, the first thickness compensation layer TCL1 may not be covered by the pixel defining layer PDL, and may be disposed within the first hole of the pixel defining layer PDL.

After the pixel defining layer PDL is formed, a fifth conductive layer (for example, the fifth conductive layer CL5 of FIG. 15) may be formed, and a portion of the fifth conductive layer may be removed to form the second thickness compensation layer TCL2 and the third thickness compensation layer TCL3. While a portion of the fifth conductive layer is removed, the second preliminary thickness compensation layer PTL2a′ may be entirely removed.

Referring further to FIG. 19, after the second thickness compensation layer TCL2 and the third thickness compensation layer TCL3 are formed, the light-emitting layer EL, the common electrode CE, the thin film encapsulation layer TFE, the optical functional layer OFL, and the second substrate SUB2 are formed, so that the display device DD of FIG. 1 may be manufactured.

As described above, in the manufacturing method of the display device DD according to the embodiments of the present disclosure, a portion of the fourth conductive layer CL4 disposed in the third pixel area PA3 may be removed using the etchant, a portion of the fifth conductive layer CL5 disposed in the second pixel area PA2 and the third pixel area PA3 may be removed, and the second preliminary thickness compensation layer PTL2a formed from the fourth conductive layer CL4 disposed in the second pixel area PA2 may be removed. Accordingly, a first thickness compensation layer TCL1 and a second thickness compensation layer TCL2 may be formed in the first pixel area PA1, and a third thickness compensation layer TCL3 may be formed in the third pixel area PA3. Accordingly, the target resonance distance may be secured without directly etching the upper transparent electrodes (e.g., the first, second, and third transparent electrodes UTE1, UTE2, and UTE3). Accordingly, a display device DD with improved durability may be easily manufactured.

In addition, a second preliminary thickness compensation layer PTL2a′ may be formed to be disposed within the second hole of the pixel definition layer PDL using the etchant. Accordingly, while forming the second thickness compensation layer TCL2 and the third thickness compensation layer TCL3, a dummy pattern may not be formed around the second upper transparent electrode UTE2, so that the target resonance distance may be easily secured without the common electrode CE being disconnected. Accordingly, it is possible to easily manufacture a display device DD with improved durability while reducing the manufacturing time and cost of the display device DD.

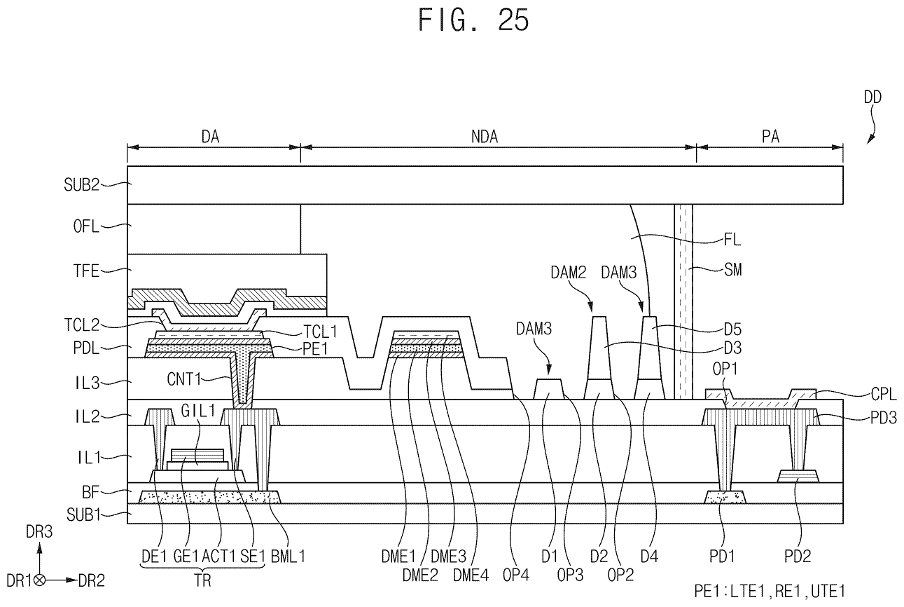

FIG. 25 is a cross-sectional view illustrating another example of a cross-section taken along a line II-II′ of FIG. 1.

Hereinafter, the overlapping content described with reference to FIG. 5 may be omitted or briefly described.

A structure of the display device DD described with reference to FIG. 25 may be substantially a same as or similar to the structure of the display device DD described with reference to FIG. 5 except for arranging the capping layer CPL.

Referring to FIG. 25, in an embodiment, the display device DD may further include a capping layer CPL. The capping layer CPL may fill the first opening OP1 exposing the surface of the third pad electrode PD3. In an embodiment, the capping layer CPL may include a transparent material. For example, the transparent material may be indium tin oxide. However, the material included in the capping layer CPL according to embodiments of the present disclosure may not be necessarily limited thereto.

In an embodiment, the capping layer CPL may include the same material as the second thickness compensation layer (e.g. the second thickness compensation layer TCL2 of FIG. 4). For example, the capping layer CPL may be formed through the same process as the second thickness compensation layer. In an embodiment, the capping layer CPL may include the same material as the third thickness compensation layer (e.g., the third thickness compensation layer TCL3 of FIG. 4). For example, the capping layer CPL may be formed through the same process as the third thickness compensation layer.

The capping layer CPL has conductivity and may be disposed to fill the first opening OP1 on the third pad electrode PD3. Accordingly, a path for foreign substances or moisture to enter through the first opening OP1 exposing one surface of the third pad electrode PD3 through the capping layer CPL may be blocked. Accordingly, the durability and lifespan of the display device DD may be further improved.

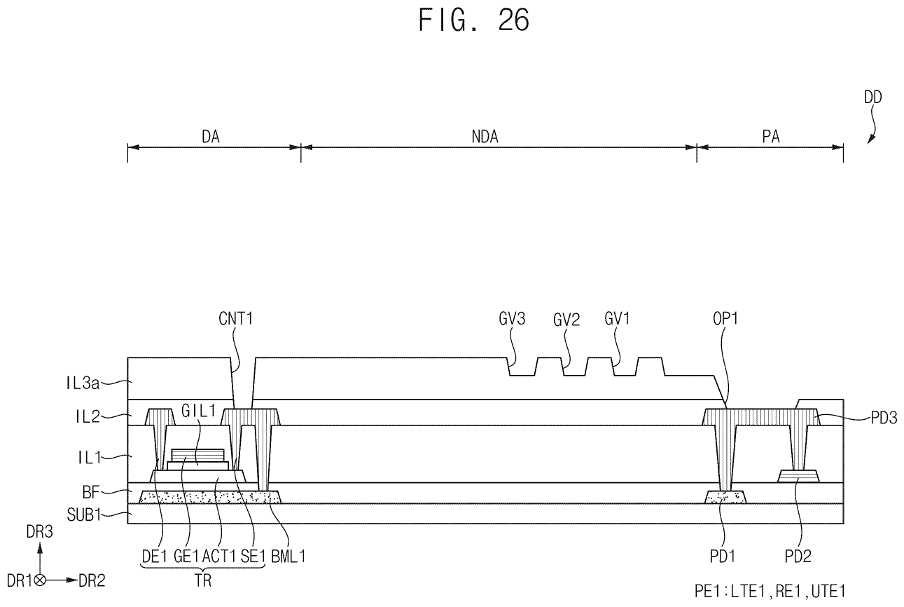

FIGS. 26, 27, 28, and 29 are cross-sectional views explaining for a method of manufacturing the display device of FIG. 25.

The overlapping contents described with reference to FIGS. 6, 7, 8, 9, 10, 11, 12, 13, 14, 15, 16, 17, and 18 and FIG. 25 may be omitted or briefly described.

Referring to FIG. 26, a preliminary third insulating layer IL3a may be disposed on a second insulating layer IL2. A first contact hole CNT1 exposing an upper surface of a first source electrode SE1 may be formed in the preliminary third insulating layer IL3a. Although only the first source electrode SE1 is illustrated in FIG. 26, contact holes extending to the second source electrode SE2 and the third source electrode SE3 of FIG. 3 may be formed in the preliminary third insulating layer IL3a.

A plurality of grooves that are sunken in the thickness direction (e.g., the third direction DR3) may be formed in the preliminary third insulating layer IL3a. For example, the plurality of grooves may include a first groove GV1, a second groove GV2, and a third groove GV3. In an embodiment, the third groove GV3 may be located closer to the display area DA than the first groove GV1 and the second groove GV2. Number, shape, location, and the like of the plurality of grooves according to embodiments of the present disclosure may be exemplary and may not be necessarily limited thereto.

In an embodiment, the plurality of grooves, the first opening OP1, and the first contact hole CNT1 may be formed through the same process. For example, the plurality of grooves may be formed based on light transmitted through a semi-transparent film of the mask, and the first contact hole CNT1 and the first opening OP1 may be formed based on light transmitted through a transmissive film of the mask. However, a formation process of each of the plurality of grooves, the first opening OP1, and the first contact hole CNT1 according to embodiments of the present disclosure may not be necessarily limited thereto.

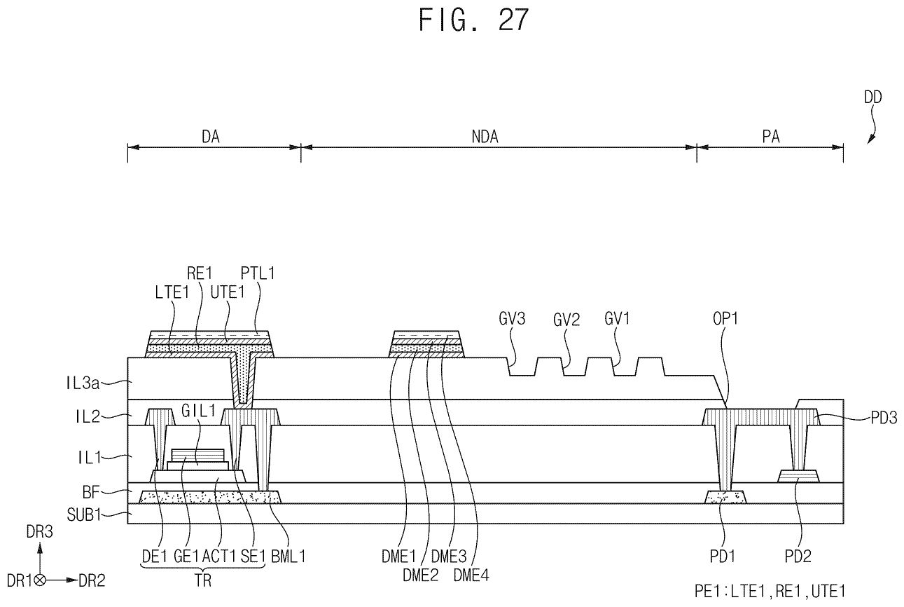

Referring to FIG. 27, in the display area DA, the first lower transparent electrode LTE1, the first reflection electrode RE1, and the first upper transparent electrode UTE1 may be formed on the third preliminary insulating layer IL3a. The first preliminary thickness compensation layer PTL1 may be formed on the first upper transparent electrode UTE1. In the non-display area NDA, a first dummy electrode DME1, a second dummy electrode DME2, a third dummy electrode DME3, and a fourth dummy electrode DME4 may be formed on the third preliminary insulating layer IL3a.

In an embodiment, the first dummy electrode DME1 may include a same material as the first lower transparent electrode LTE1. For example, the first dummy electrode DME1 may be formed through a same process as the first lower transparent electrode LTE1. In an embodiment, the second dummy electrode DME2 may include a same material as the first reflection electrode RE1. For example, the second dummy electrode DME2 may be formed through a same process as the first reflection electrode RE1. In an embodiment, the third dummy electrode DME3 may include a same material as the first upper transparent electrode UTE1. For example, the third dummy electrode DME3 may be formed through a same process as the first upper transparent electrode UTE1. In an embodiment, the fourth dummy electrode DME4 may include a same material as the first preliminary thickness compensation layer PTL1. For example, the fourth dummy electrode DME4 may be formed through a same process as the first preliminary thickness compensation layer PTL1.

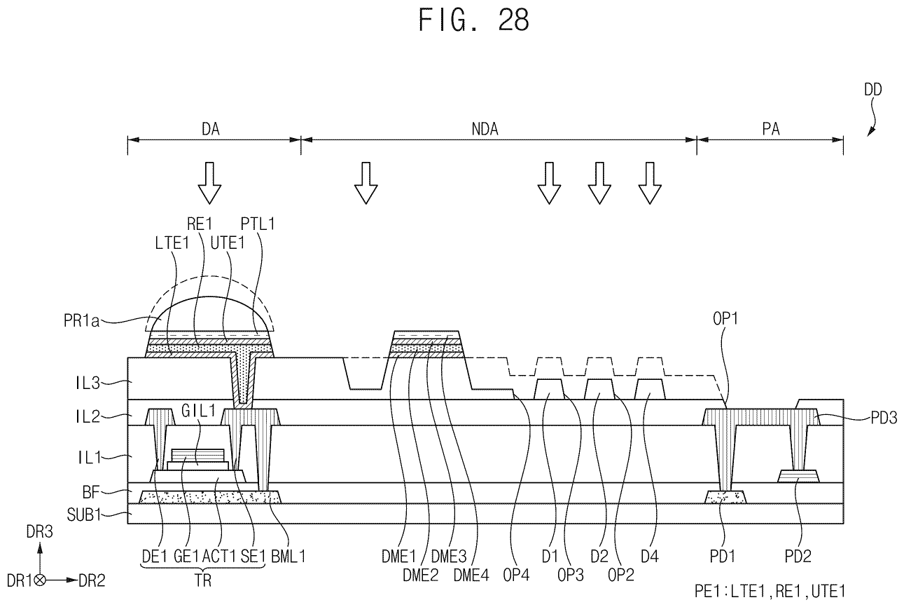

Referring to FIGS. 27 and 28, a first photoresist (e.g., the first photoresist PR1 of FIG. 11) may be formed on the first preliminary thickness compensation layer PTL1. After the first photoresist is formed, the first ashing process described with reference to FIG. 11 may be performed. While the first ashing process is performed to form the first photoresist PR1a having a reduced size, a portion of the third preliminary insulating layer IL3a may be removed. For example, a portion of the third preliminary insulating layer IL3a may be removed through the first ashing process so that the plurality of grooves extend to the upper surface of the second insulating layer IL2. In addition, a portion of the third preliminary insulating layer IL3a adjacent to the plurality of grooves may be formed as a first dummy layer D1, a second dummy layer D2, and a fourth dummy layer D4. Accordingly, a third insulating layer IL3 having a second opening OP2, a third opening OP3, and a fourth opening OP4 that expose the upper surface of the second insulating layer IL2 may be formed. In addition, the third preliminary insulating layer IL3a disposed in the pad area PDA may be entirely removed through the first ashing process.

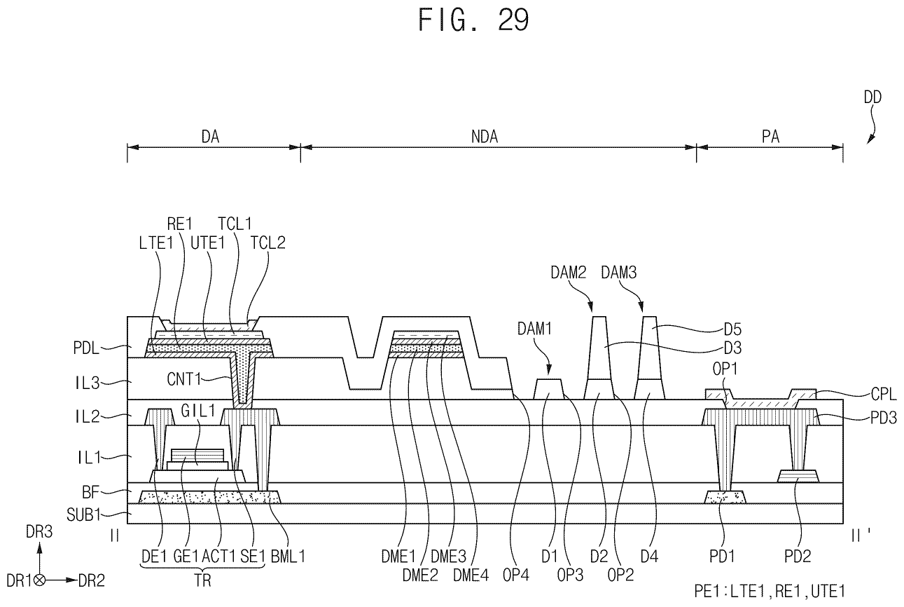

Referring to FIG. 29, after the first ashing process is performed, a first thickness compensation layer TCL1 may be formed. While the first thickness compensation layer TCL1 is formed, the capping layer CPL may be formed in the pad area PA. The capping layer CPL may include the same material as the first thickness compensation layer TCL1, and the capping layer CPL and the first thickness compensation layer TCL1 may be formed simultaneously.

After the first thickness compensation layer TCL1 is formed, the pixel defining layer PDL may be formed on the third insulating layer IL3. While the pixel defining layer PDL is formed, a third dummy layer D3 and a fifth dummy layer D5 including the same material as the pixel defining layer PDL may be formed in a non-display area NDA. After the pixel defining layer PDL is formed, a second thickness compensation layer TCL2 may be formed on the first thickness compensation layer TCL1.

Referring further to FIG. 3, after the second thickness compensation layer TCL2 is formed, an emission layer EL, the common electrode CE, the thin film encapsulation layer TFE, the optical functional layer OFL, and the second substrate SUB2 may be formed, so that the display device DD of FIG. 1 may be manufactured.

As described above, in the manufacturing method of the display device DD according to the embodiments of the present disclosure, a portion of the fourth conductive layer CL4 disposed in the third pixel area PA3 may be removed using the etchant, a portion of the fifth conductive layer CL5 disposed in the second pixel area PA2 and the third pixel area PA3 may be removed, and the second preliminary thickness compensation layer PTL2a formed from the fourth conductive layer CL4 disposed in the second pixel area PA2 may be removed. Accordingly, the first thickness compensation layer TCL1 and the second thickness compensation layer TCL2 may be formed in the first pixel area PA1, and the third thickness compensation layer TCL3 may be formed in the third pixel area PA3. Accordingly, the target resonance distance may be secured without directly etching the upper transparent electrodes (e.g., the first, second, and third transparent electrodes UTE1, UTE2, and UTE3). Accordingly, a display device DD with improved durability may be easily manufactured.

In addition, a capping layer CPL may be formed on the third pad electrode PD3 while forming the first thickness compensation layer TCL1. Accordingly, a display device DD with improved durability may be easily manufactured while shortening the manufacturing time and cost of the display device DD.

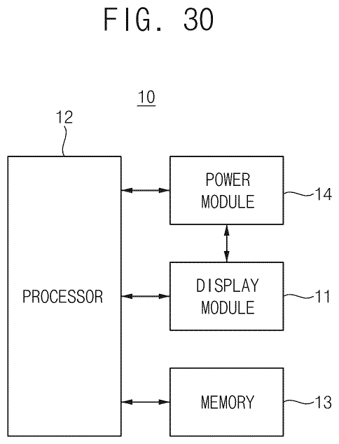

FIG. 30 is a block diagram of an electronic device according to an embodiment of the present disclosure.

Referring to FIG. 30, an electronic device 10 according to an embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal or an input control signal may be transmitted to the display module 11, and the display module 11 may process a signal received and output image information through a display screen. For example, the display device (e.g. the display device DD of FIG. 1) including the display module 11 may process the image data signal and the input control signal, and output the image data through the display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device according to the embodiments described above. In addition, a portion among the individual modules functionally included in one module may be included in the display device, and another portion may be provided separately from the display device. For example, the display device may include the display module 11, and the processor 12, the memory 13, and the power module 14 may be provided in the form of other devices within the electronic device 10 except for the display device.

In an embodiment, the electronic device 10 may include the display device manufactured by at least one manufacturing method among a method described with reference to FIGS. 6, 7, 8, 9, 10, 11, 12, 13, 14, 15, 16, 17, and 18, a method described with reference to FIGS. 20, 21, 22, 23, and 24, and a method described with reference to FIGS. 26, 27, 28, and 29.

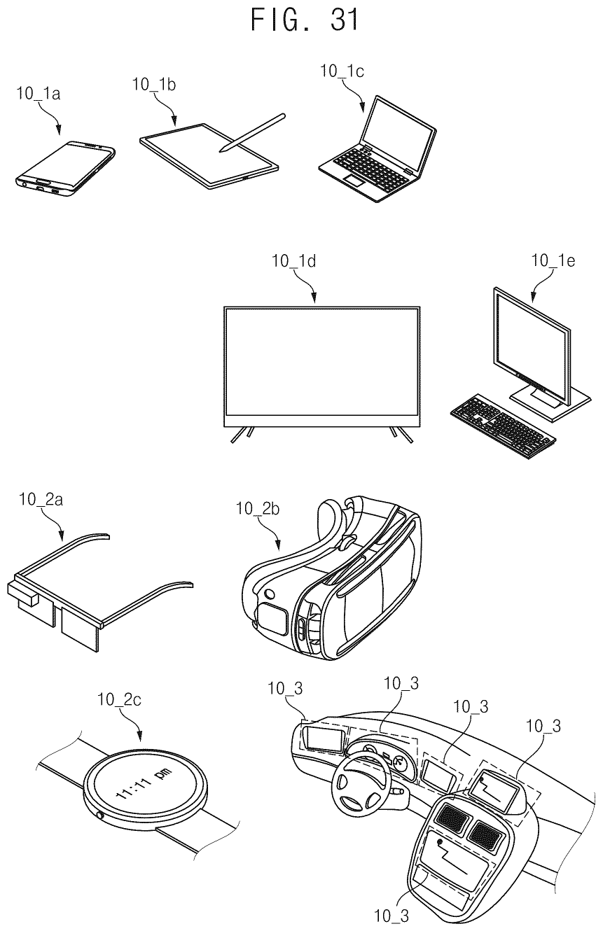

FIG. 31 is a schematic diagram of the electronic device according to various embodiments of the present disclosure.

Referring to FIG. 31, various electronic device (e.g. the electronic device 10 of FIG. 30) to which display device (e.g. the display device DD o FIG. 1) according to embodiments are applied may include not only image display electronic device such as a smart phone 10_1a, a tablet PC 10_1b, a laptop 10_1c, a TV 10_1d, and a desk monitor 10_1e, but also a wearable electronic device including display module such as smart glasses 10_2a, a head mounted display 10_2b, and a smart watch 10_2c, and a vehicle electronic device 10_3 including a dashboard, a center fascia, and display modules such as a CID (Center Information Display) and a room mirror display disposed in the dashboard.

As described above, in the electronic device 10, the display device including the display module 11 and a processor 12, the memory 13 and the power module 14 for operating the display module 11 may be disposed within the electronic device 10. Accordingly, the display device with improved light-emitting efficiency and display quality may be stably operated, and an electronic device 10 used for various purposes may be provided to the user.

The method and the device according to the embodiments may be applied to a display device included in a computer, a notebook, a mobile phone, a smartphone, a smart pad, a PMP, a PDA, an MP3 player, or the like.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display device comprising:
a substrate including a display area including a first pixel area and a second pixel area which are adjacent to each other and a pad area spaced apart from the display area;
a first reflection electrode disposed in the first pixel area on the substrate;
a second reflection electrode disposed in the second pixel area on the substrate;
a first transparent electrode disposed in the first pixel area on the first reflection electrode;
a first thickness compensation layer disposed in the first pixel area on the first transparent electrode, and including a different material with the first transparent electrode; and
a second thickness compensation layer disposed on the first thickness compensation layer, and including a center portion and an edge portion which has a first inclination angle with respect to a surface of the first thickness compensation layer.

2. The display device of claim 1, wherein the first thickness compensation layer includes an indium zinc oxide (IZO), and
wherein the second thickness compensation layer includes an indium tin oxide (ITO).

3. The display device of claim 1, further comprising:
a pixel defining layer disposed on the substrate, and covering a portion of each of the first reflection electrode, the second reflection electrode, the first transparent electrode, and the first thickness compensation layer; and
a common electrode disposed in the first pixel area and the second pixel area on the pixel defining layer, and
wherein a surface of the common electrode has a first height based on the substrate in the first pixel area, and
wherein the surface of the common electrode has a second height different from the first height based on the substrate in the second pixel area.

4. The display device of claim 3, wherein the second thickness compensation layer extends from the center portion along a side surface of the pixel defining layer.

5. The display device of claim 3, further comprising:
a second transparent electrode disposed in the second pixel area on the second reflection electrode,
wherein a first resonance distance defined as a shortest distance between the second thickness compensation layer and the common electrode is greater than a second resonance distance defined as a shortest distance between the second transparent electrode and the common electrode.

6. The display device of claim 5, further comprising:
a dummy pattern disposed in the second pixel area on the second transparent electrode, and contacting an edge portion of the second transparent electrode,
wherein the first thickness compensation layer and the dummy pattern include a same material.

7. The display device of claim 3, wherein the display area includes a third pixel area adjacent to the second pixel area,
wherein the display device further comprising:
a third reflection electrode disposed on the third pixel area on the substrate;
a third transparent electrode disposed in the third pixel area on the third reflection electrode; and
a third thickness compensation layer disposed in the third pixel area on the third transparent electrode, and
wherein a first resonance distance defined as a shortest distance between the second thickness compensation layer and the common electrode is greater than a third resonance distance defined as a shortest distance between the third thickness compensation layer and the common electrode.

8. The display device of claim 7, wherein the second thickness compensation layer and the third thickness compensation layer include a same material.

9. The display device of claim 7, wherein the third thickness compensation layer extends along a side surface of the pixel defining layer,
wherein an edge portion of the third thickness compensation layer has a second inclination angle with respect to a surface of the third transparent electrode.

10. The display device of claim 1, further comprising:
an electrode structure disposed in the pad area on the substrate;
an insulating structure disposed in the pad area on the substrate, covering at least a portion of the electrode structure, and defining an opening exposing at least a portion of the electrode structure; and
a capping layer disposed on the electrode structure, and filling the opening,
wherein the capping layer and the second thickness compensation layer includes a same material.

11. A method of manufacturing a display device, the method comprising:
forming a first pixel electrode in a first pixel area on a substrate including the first pixel area, a second pixel area, and a third pixel area adjacent to each other;
forming a first thickness compensation layer in the first pixel area on the first pixel electrode;
forming a first conductive layer in the first pixel area, the second pixel area, and the third pixel area on the first thickness compensation layer; and
forming a second thickness compensation layer directly contacting the first thickness compensation layer in the first pixel area, and including an edge portion having an inclination angle with respect to a surface of the first conductive layer.

12. The method of claim 11,wherein the forming of the first pixel electrode includes:
forming a second conductive layer in the first pixel area, the second pixel area, and the third pixel area on the substrate;
forming a third conductive layer in the first pixel area, the second pixel area, and the third pixel area on the second conductive layer;
forming a first photoresist in the pixel area on the third conductive layer;
forming a second photoresist having a thickness equal to a thickness of the first photoresist in the second area on the third conductive layer;
forming a third photoresist having a thickness less than a thickness of the first photoresist in the third pixel area on the third conductive layer; and
removing a portion of the second conductive layer spaced apart from the first photoresist, the second photoresist, and the third photo resist in a plan view.

13. The method of claim 12, wherein in the removing of the portion of the second conductive layer,
the portion of the second conductive layer is removed to form the second pixel electrode in the second pixel area and to form the third pixel electrode in the third pixel area.

14. The method of claim 13, wherein the forming of the first thickness compensation layer includes:
removing a portion of the third conductive layer space apart from the first photoresist, the second photoresist, and the third photoresist in a plan view;
removing the portion of the third conductive layer to form a first preliminary thickness compensation layer in the first pixel area on the first pixel electrode;
removing the portion of the third conductive layer to form a second preliminary thickness compensation layer in the second pixel area on the second pixel electrode;
removing the portion of the third conductive layer to form a third preliminary thickness compensation layer in the third pixel area on the third pixel electrode;
ashing each of the first photoresist, the second photoresist, and the third photoresist to expose a surface of the third preliminary thickness compensation layer; and
etching each of the first preliminary thickness compensation layer, the second preliminary thickness compensation layer, and the third preliminary thickness compensation layer using an etchant.

15. The method of claim 14, wherein performing a process of ashing includes:
ahsing the first photoresist to remove a portion of the first photoresist;
ahsing the second photoresist to remove a portion of the second photoresist; and
ahsing the third photoresist to remove entirety of the third photoresist.

16. The method of claim 14, wherein etching of the first preliminary thickness compensation layer, the second preliminary thickness compensation layer, and the third preliminary thickness compensation layer includes:
removing a portion of the first preliminary thickness compensation layer using an etchant an etching selectivity for the third conductive layer greater than an etching selectivity for the second conductive layer;
removing a portion of the second preliminary thickness compensation layer using the etchant; and
removing entirety of the third preliminary thickness compensation layer using the etchant.

17. The method of claim 14, wherein forming of the first conductive layer includes:
forming a pixel defining layer partially overlapping each of the first pixel electrode, the second pixel electrode, and the third pixel electrode in a plan view; and
depositing the first conductive layer on the first thickness compensation layer, the second preliminary thickness compensation layer, the third pixel electrode, and the pixel defining layer,
wherein in the forming of the second thickness compensation layer,
in the first pixel area, the first conductive layer is etched so that a portion of the first conductive layer extending along a side surface of the pixel defining layer.

18. The method of claim 13, further comprising:
forming a third thickness compensation layer directly contacting the third pixel electrode in the third pixel area, and including an edge portion having a second inclination angle with respect to the third thickness compensation layer by removing a portion of the first conductive layer,
wherein the forming of the third thickness compensation layer is performed simultaneously with the forming of the second thickness compensation layer.

19. The method of claim 11, further comprising:
forming a capping layer including a same material as the second thickness compensation layer on an insulating layer in a pad area on the substrate,
wherein the forming of the capping layer is performed simultaneously with the forming of the second thickness compensation layer.

20. An electronic device comprising:
one or more processors configured to output an input data signal and an input control signal; and
a display device configured to process the input data signal and the input control signal, and configured to output an image data through a display screen,
wherein the display device comprising:
a substrate including a display area including a first pixel area and a second pixel area which are adjacent to each other and a pad area spaced apart from the display area;
a first reflection electrode disposed in the first pixel area on the substrate;
a second reflection electrode disposed in the second pixel area on the substrate;
a first transparent electrode disposed in the first pixel area on the first reflection electrode;
a first thickness compensation layer disposed in the first pixel area on the first transparent electrode, and including a different material with the first transparent electrode; and
a second thickness compensation layer disposed on the first thickness compensation layer, and including a center portion and an edge portion which has an inclination angle with respect to a surface of the first thickness compensation layer.
